(19) United States
(12) Patent Application Publication
(10) Pub. No.: US 2025/0188335 A1
(43) Pub. Date: Jun. 12, 2025

(54) SHEET COMPRISING A COMPOSITE MATERIAL OF A POLYMER AND HEXAGONAL BORON NITRIDE PARTICLES AND PROCESSES FOR PRODUCING THE SAME

(71) Applicant: 3M INNOVATIVE PROPERTIES COMPANY, St. Paul, MN (US)

(72) Inventors: Steven D. Solomonson, Shoreview, MN (US); Derek J. Dehn, Maplewood, MN (US); Alexander Misura, Woodbury, MN (US); Paul T. Hines, St. Paul, MN (US); Garth V. Antila, Hudson, WI (US); Brinda B. Badri, Woodbury, MN (US); Matthew H. Frey, Cottage Grove, MN (US)

(21) Appl. No.: 18/842,243

(22) PCT Filed: Mar. 13, 2023
(86) PCT No.: PCT/IB2023/052405

§ 371 Date: Aug. 28, 2024

Related U.S. Application Data
(60) Provisional application No. 63/323,189, filed on Mar. 24, 2022.

(51) Int. Cl. C09K 5/14; B29D 7/01; B29K 105/18; B29K 509/00; C08J 5/12; C08J 9/00; C08J 9/28; C08K 7/00

(52) U.S. Cl. CPC C09K 5/14; B29D 7/01; C08J 5/121; C08J 9/0066; C08J 9/283; C08K 7/00; B29K 2023/06; B29K 2105/18; B29K 2509/00; B29K 2995/0013; C08J 2201/0522; C08J 2323/06; C08K 2201/001

(57) ABSTRACT

The present disclosure relates to a sheet comprising a composite material comprising a polymer and hexagonal boron nitride particles, wherein the hexagonal boron nitride particles comprise platelet-shaped hexagonal boron nitride particles, and wherein the platelet-shaped hexagonal boron nitride particles are oriented in a direction perpendicular to the direction of the plane of the sheet, and wherein the composite material comprises at least 70 percent by weight of the hexagonal boron nitride particles, based on the total weight of the composite material, and wherein the sheet has a through-plane thermal conductivity of more than 12 W/m*K. The present disclosure further relates to processes for producing said sheet.

### TECHNICAL FIELD

The present disclosure relates to a sheet comprising a composite material comprising a polymer and hexagonal boron nitride particles, wherein the hexagonal boron nitride particles comprise platelet-shaped hexagonal boron nitride particles being oriented in a direction perpendicular to the direction of the plane of the sheet.

### BACKGROUND

Thermally conductive polymer compounds are used for thermal management solutions. For electronic devices, like in mobile devices, for LED technology, for electric vehicles, and for 5G technology, there is a growing demand for thermally conductive and electrically insulating polymer materials. To improve performance of these materials, thermal conductivity needs to be increased. To this end, thermally conductive fillers are used such as boron nitride, alumina, aluminum nitride, silicon carbide, silicon nitride, magnesium oxide or minerals. With increasing load of thermally conductive fillers, higher values for thermal conductivity can be obtained. The maximum loads of fillers in compounds are typically limiting thermal conductivities that can be achieved.

For 5G technology applications, materials are needed that have high thermal conductivity, electrical insulation, and low permittivity (i.e., low dielectric constant), and low dissipation factor. For many 5G applications, these thermal interface materials are needed in the form of a thin film or sheet. Oftentimes it is desired that thermal conductivity of these films or sheets is as high as possible in a direction perpendicular to the plane of the film, i.e., a high through-plane thermal conductivity is required.

US 2010/0200801 A1 discloses a thermal interface material comprising a base matrix comprising a polymer and 5 to 90 wt. %, preferably 20 to 60 wt. %, of boron nitride filler having a platelet structure, wherein the platelet structure of the boron nitride particles is substantially aligned for the thermal interface material to have a bulk thermal conductivity of at least 1 W/m*K. The thermal interface material is extruded into sheets. As a second step, the sheets may be stacked, pressed, cured and sliced in a direction perpendicular to the stacking direction, or the sheet may be compression rolled into a roll, cured and sliced into a plurality of circular pads in a direction perpendicular to the rolling direction.

WO 2019/097445 A1 discloses a polymer matrix composite comprising a porous polymeric network, and a plurality of thermally conductive particles distributed within the polymeric network structure.

There is a need for thermally conductive, electrically insulating thermal interface materials having a high through-plane thermal conductivity, and good dielectric properties, i.e., low dielectric constant and low dielectric dissipation factor.

As used herein, “a”, “an”, “the”, “at least one” and “one or more” are used interchangeably. The term “comprise” shall include also the terms “consist essentially of” and “consists of”.

### SUMMARY

In a first aspect, the present disclosure relates to a sheet comprising a composite material comprising a polymer and hexagonal boron nitride particles, wherein the hexagonal boron nitride particles comprise platelet-shaped hexagonal boron nitride particles, and wherein the platelet-shaped hexagonal boron nitride particles are oriented in a direction perpendicular to the direction of the plane of the sheet, and wherein the composite material comprises at least 70 percent by weight of the hexagonal boron nitride particles, based on the total weight of the composite material, and wherein the sheet has a through-plane thermal conductivity of more than 12 W/m*K.

In another aspect, the present disclosure also relates to a process for producing a sheet as disclosed herein, the process comprising
providing a polymer, a solvent, and hexagonal boron nitride particles comprising platelet-shaped hexagonal boron nitride particles,
combining the polymer, the solvent, and the hexagonal boron nitride particles to form a suspension of hexagonal boron nitride particles in a polymer-solvent solution, wherein the polymer in the polymer-solvent solution has a melting point, and wherein the solvent has a boiling point, and wherein combining the polymer, the solvent, and the hexagonal boron nitride particles is conducted at a temperature above the melting point of the polymer in the polymer-solvent solution, and below the boiling point of the solvent,
forming the suspension into a film, wherein the platelet-shaped hexagonal boron nitride particles are oriented in a direction parallel to the direction of the plane of the film,
inducing phase separation of the polymer from the solvent,
removing at least a portion of the solvent from the film to obtain a porous film,
optionally compressing the porous film to obtain a densified film,
stacking multiple layers either of the porous film or of the densified film one upon another to obtain a film stack,
pressing the film stack to obtain a bonded film stack, and
slicing a sheet from the bonded film stack in a direction perpendicular to the planes of the stacked film layers. In another aspect, the present disclosure also relates to a process for producing a sheet as disclosed herein, the process comprising
providing a polymer, a solvent, and hexagonal boron nitride particles comprising platelet-shaped hexagonal boron nitride particles,
combining the polymer, the solvent, and the hexagonal boron nitride particles to form a slurry, wherein the slurry is a suspension of the polymer and the hexagonal boron nitride particles in the solvent, and wherein the polymer has a melting point, and wherein the solvent has a boiling point, and wherein combining the polymer, the solvent, and the hexagonal boron nitride particles is conducted below the melting point of the polymer, and below the boiling point of the solvent,
forming the slurry into a film, wherein the platelet-shaped hexagonal boron nitride particles are oriented in a direction parallel to the direction of the plane of the film,
heating the film in an environment to retain at least 90 percent by weight of the solvent in the film, based on the weight of the solvent in the film, and solubilizing at least 50 percent by weight of the polymer in the solvent, based on the total weight of the polymer,
inducing phase separation of the polymer from the solvent,
removing at least a portion of the solvent from the film to obtain a porous film,
optionally compressing the porous film to obtain a densified film,
stacking multiple layers either of the porous film or of the densified film one upon another to obtain a film stack,
pressing the film stack to obtain a bonded film stack, and
slicing a sheet from the bonded film stack in a direction perpendicular to the planes of the stacked film layers.

The sheet disclosed herein comprises highly oriented boron nitride platelet-shaped particles and has consequently highly anisotropic properties, particularly highly anisotropic thermal conductivity properties.

The film disclosed herein comprises boron nitride platelet-shaped particles oriented perpendicularly to the plane of the sheet and has a high through-plane thermal conductivity.

The sheet as disclosed herein allows to remove heat faster and more efficiently, due to the high through-plane thermal conductivity. Compared to other polymer sheets filled with boron nitride, the sheets disclosed herein have a higher through-plane thermal conductivity than in-plane thermal conductivity.

In addition, the sheet disclosed herein has good dielectric properties, specifically low permittivity and low dissipation factor.

Typically, the sheet disclosed herein is free of silicone.

“Phase separation”, as used herein, refers to a process in which particles are uniformly dispersed in a homogeneous polymer-solvent solution that is transformed (e.g., by a change in temperature or solvent concentration) into a continuous three-dimensional composite material, i.e., a polymer matrix composite. In the first process disclosed herein, phase separation is achieved via solvent induced phase separation (SIPS) using a wet or dry process, or thermally induced phase separation (TIPS) processes. In the second process disclosed herein, the desired article (i.e., a film) is formed before the polymer becomes miscible with the solvent and the phase separation is a thermally induced phase separation process.

“Miscible” as used herein refers to the ability of substances to mix in all proportions (i.e., to fully dissolve in each other at any concentration), forming a solution, wherein for some solvent-polymer systems heat may be needed for the polymer to be miscible with the solvent. By contrast, substances are immiscible if a significant proportion does not form a solution. For example, butanone is significantly soluble in water, but these two solvents are not miscible because they are not soluble in all proportions.

Typically, the maximum particle loading that can be achieved in traditional particle-filled composites (dense polymeric films, adhesives, etc.), is not more than about 40 to 60 vol. %, based on the volume of the particles and the binder. Incorporating more than 60 vol. % particles into traditional particle-filled composites typically is not achievable because such high particle loaded materials cannot be processed via coating or extrusion methods and/or the resulting composite becomes very brittle. Traditional composites also typically fully encapsulate the particles with binder, preventing access to the particle surfaces and minimizing potential particle-to-particle contact. Typically, the thermal conductivity of a thermally conductive particle-filled composite increases with particle loading, making higher particle loadings desirable. Surprisingly, the high levels of solvent and the phase-separated morphologies, obtained with the processes described herein, enable relatively high particle loadings with relatively low amounts of high molecular weight binder. Although not wanting to be bound by theory, it is believed that another advantage of embodiments of the composite material described herein, is that the particles are not fully coated with binder, enabling a high degree of particle surface contact, without masking due to the porous nature of the binder. Compression of the film significantly enhances the particle-to-particle contact.

### BRIEF DESCRIPTION OF THE DRAWINGS

The present disclosure is explained in more detail on the basis of the drawings, in which

FIGS. 1a and 1b show scanning electron micrographs of a cross-section of a sheet as disclosed herein; and

FIG. 2 schematically shows the stacking and slicing steps of the processes for producing a sheet as disclosed herein.

### DETAILED DESCRIPTION

The sheet as disclosed herein comprises a composite material comprising hexagonal boron nitride particles. The hexagonal boron nitride particles comprise platelet-shaped hexagonal boron nitride particles. Platelet-shaped hexagonal boron nitride particles may also be referred to as flake-shaped or scale-like hexagonal boron nitride particles.

The platelet-shaped hexagonal boron nitride particles have a basal plane. The basal plane of the platelet-shaped hexagonal boron nitride particles is oriented perpendicularly to the direction of the plane of the sheet. In other words, in the sheet as disclosed herein, the platelet-shaped hexagonal boron nitride particles are oriented in a direction perpendicular to the direction of the plane of the sheet.

The orientation in a direction perpendicular to the direction of the plane of the sheet is evidenced by scanning electron microscopy and by X-ray diffraction measurements, showing that hexagonal boron nitride particles in the composite material are oriented in a direction perpendicular to the direction of the plane of the sheet.

Typically, at least 50 percent by weight of the hexagonal boron nitride particles are platelet-shaped hexagonal boron nitride particles, based on the total weight of the hexagonal boron nitride particles. Preferably, at least 80 percent by weight of the hexagonal boron nitride particles are platelet-shaped hexagonal boron nitride particles, based on the total weight of the hexagonal boron nitride particles. It is also possible that all of the hexagonal boron nitride particles are platelet shaped. A portion of, or even all of, the platelet-shaped hexagonal boron nitride particles may be agglomerated to boron nitride agglomerates. The platelet-shaped hexagonal boron nitride particles may also be non-agglomerated.

The sheet as disclosed herein comprises a composite material comprising a polymer. In some embodiments, the polymer may be selected from the group consisting of polyurethane, polyester, polyamide, polyether, polycarbonate, polyimide, polysulfone, polyethersulfone, polyphenylene oxide, polyacrylate, polymethacrylate, polyacrylonitrile, polyolefin, styrene, styrene-based copolymer, styrene-base copolymer, chlorinated polymer, fluorinated polymer, copolymers of ethylene and chlorotrifluoroethylene, and combinations thereof. The styrene-based copolymer may be a styrene-based random copolymer, or a styrene-based block copolymer. The polyolefin may be an ultra-high molecular weight polyethylene (UHMWPE) or a polypropylene.

The polymer may comprise, consist essentially of, or consist of at least one thermoplastic polymer. Exemplary thermoplastic polymers include polyurethane, polyester (e.g., polyethylene terephthalate, polybutylene terephthalate, and polylactic acid), polyamide (e.g., nylon 6, nylon 6,6, nylon 12 and polypeptide), polyether (e.g., polyethylene oxide and polypropylene oxide), polycarbonate (e.g., bisphenol-A-polycarbonate), polyimide, polysulphone, polyethersulfone, polyphenylene oxide, polyacrylate (e.g., thermoplastic polymers formed from the addition polymerization of monomer(s) containing an acrylate functional group), polymethacrylate (e.g., thermoplastic polymers formed from the addition polymerization of monomer(s) containing a methacrylate functional group), polyolefin (e.g., polyethylene and polypropylene), styrene and styrene-based, random and block copolymer, chlorinated polymer (e.g., polyvinyl chloride), fluorinated polymer (e.g., polyvinylidene fluoride; copolymers of tetrafluoroethylene, hexafluoropropylene and vinylidene fluoride; copolymers of ethylene, tetrafluoroethylene; hexafluoropropylene; and polytetrafluoroethylene), and copolymers of ethylene and chlorotrifluoroethylene. In some embodiments, thermoplastic polymers include homopolymers or copolymers (e.g., block copolymers or random copolymers). In some embodiments, thermoplastic polymers include a mixture of at least two thermoplastic polymer types (e.g., a mixture of polyethylene and polypropylene or a mixture of polyethylene and polyacrylate). In some embodiments, the thermoplastic polymer may be at least one of polyethylene (e.g., ultra-high molecular weight polyethylene), polypropylene (e.g., ultra-high molecular weight polypropylene), polylactic acid, poly (ethylene-co-chlorotrifluoroethylene) and polyvinylidene fluoride. In some embodiments, the thermoplastic polymer is a single thermoplastic polymer (i.e., it is not a mixture of at least two thermoplastic polymer types). In some embodiments, the thermoplastic polymers consist essentially of, or consist of, polyethylene (e.g., ultra-high molecular weight polyethylene).

In some embodiments, the thermoplastic polymer used to make the composite material of the sheet disclosed herein are particles having a particle size less than 1000 (in some embodiments, in the range from 1 to 10, 10 to 30, 10 to 50, 30 to 100, 10 to 200, 10 to 500, 100 to 200, 200 to 500, 500 to 1000) micrometers.

In some embodiments, the polymer used to make the composite material of the sheet disclosed herein has a number average molecular weight in a range from 5×10⁴ to 1×10⁷ (in some embodiments, in a range from 1×10⁶ to 8×10⁶, 2×10⁶ to 6×10⁶, or even 2×106 to 5×106) g/mol. For purposes of the present disclosure, the number average molecular weight can be measured by known techniques in the art (e.g., gel permeation chromatography (GPC). GPC may be conducted in a suitable solvent for the thermoplastic polymer, along with the use of narrow molecular weight distribution polymer standards (e.g., narrow molecular weight distribution polystyrene standards). Thermoplastic polymers are generally characterized as being partially crystalline, exhibiting a melting point. In some embodiments, the thermoplastic polymer may have a melting point in a range from 120 to 350 (in some embodiments, in a range from 120 to 300, 120 to 250, or even 120 to 200)° C. The melting point of the thermoplastic polymer can be measured by known techniques in the art (e.g., the on-set temperature measured in a differential scanning calorimetry (DSC) test, conducted with a 5 to 10 mg sample, at a heating scan rate of 10° C./min., while the sample is under a nitrogen atmosphere).

In some embodiments, the polymer used to make the composite material of the sheet disclosed herein is an ultra-high molecular weight polyethylene (UHMWPE) having a number average molecular weight in a range from 5×10⁴ to 1×10⁷ (in some embodiments, in a range from 1×10⁶ to 8×10⁶, 2×10⁶ to 6×10⁶, or even 2×10⁶ to 5×10⁶) g/mol.

The hexagonal boron nitride particles are dispersed in the polymer, i.e., the polymer is a matrix material for the hexagonal boron nitride particles. The hexagonal boron nitride particles have a direct particle-to-particle contact in the composite material, i.e., continuous paths of thermally conductive hexagonal boron nitride particles are formed in the composite material. The direct particle-to-particle contact and the continuous paths of thermally conductive hexagonal boron nitride particles are evidenced by the high through-plane thermal conductivity of the composite material of the sheet.

The degree of orientation of the platelet-shaped hexagonal boron nitride particles in the film can be characterized by the orientation index, measured on a sheet sample. The orientation index of hexagonal boron nitride with isotropic orientation of the platelet-shaped hexagonal boron nitride particles, thus without preferred orientation, has a value of 1. For platelet-shaped hexagonal boron nitride particles being oriented parallelly to the plane of the sheet, the orientation index decreases with the degree of parallel orientation in the sheet sample and has values less than 1. For platelet-shaped hexagonal boron nitride particles being oriented perpendicularly to the plane of the sheet, the orientation index increases with the degree of perpendicular orientation in the sheet sample and has values greater than 1. As used herein, by “the platelet-shaped hexagonal boron nitride particles are oriented perpendicularly to the plane of the sheet” it is to be understood that the orientation index is greater than 4.0. As used herein, by “the platelet-shaped hexagonal boron nitride particles are oriented parallelly to the plane of the sheet” it is to be understood that the orientation index is at most 0.5.

The orientation index of the sheet as disclosed herein is greater than 4.0. The orientation index of the sheet may be at least 4.5, or at least 5, or at least 6, or at least 7, or at least 8, or at least 10.Preferably, the orientation index of the sheet is at least 6.

The orientation index is determined by X-ray diffractometry. For this, the ratio of the intensities of the (100) and of the (002) reflection of hexagonal boron nitride (hBN) measured on X-ray diffraction diagrams of a sheet sample is determined and is divided by the corresponding ratio for an ideal, unoriented, i.e., isotropic, hBN sample. This ideal ratio can be determined from Powder Diffraction Pattern (PDF) #01-073-2095 of the International Centre for Diffraction Data (ICDD) data (2020) and is 0.147. The theoretical peak positions of (002) and (100) reflections are at 26.7 and 41.6 degrees, respectively. Peak intensities of (002) and (100) reflections are measured from peak area at these positions. The orientation index (OI) can be determined from the formula:

$$O I = \frac{{I}_{( 1 \; 00 ) , sample} / {I}_{( 0 \; 02 ) , sample}}{{I}_{( 1 \; 00 ) , theo retical} / {I}_{( 002 ) , theoretical}} = \frac{{I}_{( 100 ) , sample} / {I}_{( 0 \; 02 ) , sample}}{0.147}$$

The composite material comprises at least 70 percent by weight of the hexagonal boron nitride particles, based on the total weight of the composite material.

The composite material may comprise at least 80, or at least 85, or at least 90, or more than 90, or at least 91, or at least 92, or at least 93, or at least 94, or at least 95, or at least 96 percent by weight of the hexagonal boron nitride particles, based on the total weight of the composite material.

The composite material may comprise from 70 to 98, or from 80 to 98, or from 85 to 98, or from 90 to 98, or from more than 90 to 98, or from 91 to 98, or from 92 to 98, or from 93 to 98, or from 94 to 98, or from 95 to 98, or from 96 to 98 percent by weight of the hexagonal boron nitride particles, based on the total weight of the composite material.

The composite material may comprise at least 2 percent by weight of the polymer, based on the total weight of the composite material. The composite material may comprise at most 30, or at most 20 percent by weight of the polymer, based on the total weight of the composite material. The composite material may comprise from 2 to 30, or from 2 to 20, or from 2 to 15, or from 2 to 10, or from 2 to 9, or from 2 to 8, or from 2 to 7, or from 2 to 6, or from 2 to 5, or from 2 to 4 percent by weight of the polymer, based on the total weight of the composite material.

The sheet disclosed herein has a through-plane thermal conductivity of more than 12 W/m*K. The through-plane thermal conductivity of the sheet may be at least 15 W/m*K, or at least 18 W/m*K, or at least 20 W/m*K, or at least 25 W/m*K, or at least 30 W/m*K, or at least 35 W/m*K, or at least 40 W/m*K, or at least 45 W/m*K, or at least 50 W/m*K. The through-plane thermal conductivity may be from more than 12 W/m*K to 25 W/m*K, or from more than 12 to 65 W/m*K, or from 15 W/m*K to 25 W/m*K, or from 15 W/m*K to 65 W/m*K, or from 20 W/m*K to 65 W/m*K, or from 30 to 65 W/m*K, or from 40 W/m*K to 65 W/m*K.

The through-plane thermal conductivity of the sheet is higher than the in-plane thermal conductivity of the sheet. Typically, the ratio of the through-plane thermal conductivity to the in-plane thermal conductivity of the sheet is at least 2, and may be at least 3, or at least 4, or at least 5.

The through-plane thermal conductivity of the sheet can be measured using the laser flash analysis method according to ASTM E1461 (2013). The through-plane thermal conductivity can also be measured according to ASTM D-5470-17 (standard test method for thermal interface materials). The through-plane thermal conductivity can be measured on sheet samples.

The in-plane thermal conductivity of the sheet may be at least 2 W/m*K. The in-plane thermal conductivity of the sheet can be measured using the laser flash analysis method according to ASTM E1461 (2013).

The composite material comprised in the sheet disclosed herein may be electrically insulating. The electrical resistivity of the composite material comprised in the sheet may be at least 1×10¹⁰ Ω*m.

The mean particle size (d₅₀) of the hexagonal boron nitride particles used for the sheet disclosed herein may be from 0.5 to 500 μm, or from 3 to 500 μm.

The mean particle size (d₅₀) of the platelet-shaped hexagonal boron nitride particles used for the sheet disclosed herein may be from 0.5 to 100 μm, or from 3 to 100 μm.

Preferably, the mean particle size (d₅₀) of the hexagonal boron nitride particles is at least 5 μm, more preferably at least 8 μm. In some embodiments, the mean particle size (d₅₀) is from 5 to 50 μm, or from 5 to 30 μm, or from 8 to 30 μm, or from 30 to 60 μm, or from 40 to 50 μm, or from 8 to 15 μm, or from 10 to 12 μm. The mean particle size (d₅₀) can be measured by laser diffraction.

The mean aspect ratio of the platelet-shaped hexagonal boron nitride particles typically is at least 5. The aspect ratio is the ratio of the diameter to the thickness of the platelet-shaped hexagonal boron nitride particles. As used herein, the platelet-shaped hexagonal boron nitride particles are also referred to as boron nitride platelets. The aspect ratio of the boron nitride platelets may be at least 10, or at least 15, or at least 20. The mean aspect ratio of the boron nitride platelets may also be up to 40, or up to 100. The mean aspect ratio of the boron nitride platelets may be from 7 to 20, or from 20 to 40, or from 7 to 40, or from 10 to 40, or from 50 to 100, or from 5 to 500. Typically, the mean aspect ratio of the boron nitride platelets is at most 500. The mean aspect ratio can be measured by scanning electron microscopy (SEM), by determining the aspect ratio of 20 particles, and calculating the mean value of the 20 individual values determined for the aspect ratio. The aspect ratio of an individual boron nitride platelet is determined by measuring the diameter and the thickness of the boron nitride platelet and calculating the ratio of the diameter to the thickness. Required magnification of the SEM images used to measure diameter and thickness of boron nitride platelets depends on the size of the platelets. Magnification should be at least 1000×, preferably at least 2000×. Where appropriate, i.e., for smaller platelets with a mean particle size (d₅₀) of 5 to 10 μm, a magnification of 5000× should be used.

The hexagonal boron nitride particles may comprise agglomerates of primary particles of hexagonal boron nitride, the primary particles comprising platelet-shaped hexagonal boron nitride particles. The hexagonal boron nitride particles may also consist of agglomerates of primary particles of hexagonal boron nitride, the primary particles comprising platelet-shaped hexagonal boron nitride particles. The agglomerates of primary particles of hexagonal boron nitride may also be referred to as “boron nitride agglomerates”. The mean particle size (d₅₀) of the boron nitride agglomerates may be at most 500 μm, or at most 250 μm, or at most 150 μm, or at most 100 μm. The mean particle size (d₅₀) of the boron nitride agglomerates may be at least 20 μm, at least 30 μm, or at least 50 μm. The mean particle size (d₅₀) of the agglomerates may be from 20 to 500 μm, or from 20 to 400 μm, or from 30 to 500 μm, or from 30 to 300 μm, or from 50 to 400 μm, or from 30 to 50 μm, or from 50 to 100 μm, or from 100 to 150 μm, or from 100 to 200 μm, or from 200 to 400 μm. The mean particle size (d₅₀) of the primary particles of hexagonal boron nitride may be from 3 to 50 μm, or from 3 to 30 μm, or from 5 to 30 μm, or from 8 to 30 μm, or from 8 to 15 μm, or from 10 to 15 μm, or from 10 to 12 μm. The mean particle size (d₅₀) of the boron nitride agglomerates and of the primary particles can be measured by laser diffraction. The boron nitride agglomerates may have any shape, e.g., spherical, irregularly shaped or flake-shaped. The flake-shaped agglomerates may have an aspect ratio of from 1 to 20.

In some embodiments, the hexagonal boron nitride particles may comprise, or consist of, agglomerates of primary particles of hexagonal boron nitride, the primary particles comprising platelet-shaped hexagonal boron nitride particles, wherein the mean particle size (d₅₀) of the agglomerates is from 30 to 300 μm, and wherein the mean particle size (d₅₀) of the primary particles of hexagonal boron nitride is from 8 to 15 μm.

In some embodiments, if boron nitride agglomerates are used as hexagonal boron nitride particles, the agglomerates may be partially or fully disintegrated into the primary particles in the final product, i.e., the sheet. In some embodiments, if boron nitride agglomerates are used as hexagonal boron nitride particles, such as flake-shaped boron nitride agglomerates, a portion or all of the agglomerates may still be present in the form of agglomerates in the final product, i.e., the agglomerates may not have disintegrated into the primary particles in the sheet.

The hexagonal boron nitride particles may also comprise non-agglomerated platelet-shaped hexagonal boron nitride particles. The hexagonal boron nitride particles may also consist of non-agglomerated platelet-shaped hexagonal boron nitride particles. The mean particle size (d₅₀) of the non-agglomerated platelet-shaped hexagonal boron nitride particles may be from 3 to 100 μm, preferably from 5 to 30 μm. The mean particle size (d₅₀) of the non-agglomerated platelet-shaped hexagonal boron nitride particles may also be from 10 to 100 μm, or from 10 to 50 μm, or from 30 to 70 μm, or from 30to 60 μm, or from 40 to 50 μm.

In some embodiments, mixtures of agglomerates and non-agglomerated platelet-shaped hexagonal boron nitride particles may be used.

The composite material and the sheet may have a porosity of up to 40%, or of up to 30%, or of up to 20%. The composite material and the sheet may have a porosity of at least 1%, or of at least 2%, or of at least 3%, or of at least 4%, or of at least 5%, or of at least 8%, or of at least 10%. In some embodiments, the composite material and the sheet has a porosity of from 0.5 to 40%, or from 0.5 to 30%, or from 0.5 to 20%, or from 1 to 40%, or from 1 to 30%, or from 1 to 20%, or from 2 to 40%, or from 2 to 30%, or from 2 to 20%, or from 5 to 40%, or from 5 to 30%, or from 5 to 20%. In some embodiments, the composite material and the sheet has a porosity of 0%.

The composite material and the sheet may have a density of at least 60%, or of at least 70%, or of at least 80%, or even of at least 90% of theoretical density. The composite material and the sheet may have a density of up to 100%, or of up to 99.5%, or of up to 99%, or of up to 98%, or of up to 97%, or of up to 96%, or of up to 95%, or of up to 92%, or of up to 90% of theoretical density. The composite material and the sheet may have a density of from 60 to 95%, or from 70 to 95%, or from 80to 95%, or from 60 to 98%, or from 70 to 98%, or from 80 to 98%, or from 60 to 99%, or from 70 to 99%, or from 80 to 99%, or from 60 to 99.5%, or from 70 to 99.5%, or from 80 to 99.5%, or from 60 to 100%, or from 70 to 100%, or from 80 to 100% of theoretical density. The theoretical density can be calculated from the known densities of the components of the composite material and the sheet, and from the weight fractions of the components.

The composite material comprised in the sheet disclosed herein, and the sheet, has good dielectric properties. Typically, the composite material and the sheet has a dielectric dissipation factor (Df) of at most 0.009 at 5.2 GHz and may be from 0.0001 to 0.009 at 5.2 GHz. The dielectric constant or relative permittivity (Dk) of the composite material and the sheet typically is at most 5.0 at 5.2 GHz and may be from 2.0 to 4.0 at 5.2 GHz.

The presence of pores in the composite material and the sheet may improve the dielectric properties of the composite material and the sheet. Furthermore, the presence of pores in the composite material and the sheet allows the composite material and the sheet to be compressible which may be desirable for some applications. The pores in the composite material and the sheet should be of small size and homogeneously distributed in the composite material and the sheet.

In some embodiments of the sheet disclosed herein, the composite material comprised in the sheet does not comprise fibers, such as carbon fibers, glass fibers or fibers made from other materials.

The sheet disclosed herein may have a Shore D hardness of at most 150. The Shore D hardness of the sheet may be from 20 to 150, or from 30 to 150, or from 30 to 100. The sheet may also have a lower or higher hardness. The thickness of the sheet disclosed herein may be from 0.01 mm to 6 mm, or from 0.05 mm to 6 mm, or from 0.1 to 3 mm, or from 0.5 to 2 mm. The size of the hexagonal boron nitride particles may be selected depending on the film thickness. The width and the length of the sheet may be up to several inches (e.g., 1 inch, 5 inches, 10 inches, 50 inches) or larger. Typically, the sheet has a constant thickness over the width and the length of the sheet. The sheet also may have a variable thickness, i.e., the thickness of the sheet is not constant over the width and length of the sheet.

The composite material may further comprise further thermally conductive fillers, such as alumina, or other fillers.

In some embodiments of the sheet disclosed herein, the composite material may further comprise an organic liquid. The amount of organic liquid comprised in the composite material may be from 0.1 to 10 percent by weight, based on the total weight of the composite material. Useful organic liquids that may be comprised in the composite material are non-volatile organic liquids that are of sufficient surface energy to wet the pores or stay entrapped in the pores. The organic liquid that may be comprised in the composite material may be, for example, at least one of mineral oil, paraffin oil/wax, orange oil, vegetable oil, castor oil, or palm kernel oil. The organic liquid comprised in the composite material may reduce the hardness of the composite material and the sheet and make it softer.

Small quantities of other additives may be added to the composite material to impart additional functionality or act as processing aids. These include viscosity modifiers (e.g., fumed silica, block copolymers, and wax), plasticizers, thermal stabilizers (e.g., such as available, for example, under the trade designation “Irganox 1010” from BASF, Ludwigshafen, Germany), antimicrobials (e.g., silver and quaternary ammonium), flame retardants, antioxidants, dyes, pigments, and ultraviolet (UV) stabilizers. Also thermally conductive particles such as carbon or hexagonal boron nitride with a low particle size (e.g., an average particle size (d₅₀) of less than 1 μm) may be used as viscosity modifiers.

Optionally, elastomers may be added to the composite material to improve elasticity, i.e., to reduce brittleness, of the composite material. Any elastomer that can be mixed or blended in with the polymer and the hexagonal boron nitride particles may be used. Suitable elastomers are, e.g., Santoprene 8211-35, available from Celanese (Irving, TX, US), Kraton 1645, available from Kraton (Houston, TX, US), Vector Thermoplastic Elastomers 2518, available from TSRC Corporation (Taiwan), Kraton D11671 PT, available from Kraton (Houston, TX, US), and Pebax 4033, available from Arkema (Colombes, France).

In some embodiments of the sheet disclosed herein, the composite material comprises at least 70, or at least 80, or at least 85, or at least 90, or more than 90, or at least 91, or at least 92 percent by weight of the hexagonal boron nitride particles, based on the total weight of the composite material, and the composite material has a porosity of at least 2%, preferably of 2 to 30%.

In some embodiments of the sheet disclosed herein, the composite material comprises at least 70, or at least 80, or at least 85, or at least 90, or more than 90, or at least 91, or at least 92 percent by weight of the hexagonal boron nitride particles, based on the total weight of the composite material, and the sheet has a through-plane thermal conductivity of at least 15 W/m*K, or of at least 20 W/m*K.

In some embodiments of the sheet disclosed herein, the composite material comprises at least 70, or at least 80, or at least 85, or at least 90, or more than 90, or at least 91, or at least 92 percent by weight of the hexagonal boron nitride particles, based on the total weight of the composite material, and the sheet has an orientation index of at least 6, or of at least 8, or of at least 10.

In some embodiments of the sheet disclosed herein, the composite material comprises at least 70, or at least 80, or at least 85, or at least 90, or more than 90, or at least 91, or at least 92 percent by weight of the hexagonal boron nitride particles, based on the total weight of the composite material, and the composite material has a porosity of at least 2%, preferably of 2 to 30%, and the sheet has a through-plane thermal conductivity of at least 15 W/m*K, or of at least 20 W/m*K, and the sheet has an orientation index of at least 6, or of at least 8, or of at least 10.

In some embodiments of the sheet disclosed herein, the hexagonal boron nitride particles comprise or consist of non-agglomerated platelet-shaped hexagonal boron nitride particles having a mean particle size (d₅₀) of from 3 to 100 μm, preferably from 5 to 30 μm.

In some embodiments of the sheet disclosed herein, the hexagonal boron nitride particles comprise agglomerates of primary particles of hexagonal boron nitride, and the primary particles comprise platelet-shaped hexagonal boron nitride particles, and the mean particle size (d₅₀) of the agglomerates is from 30 to 500 μm, and the mean particle size (d₅₀) of the primary particles of hexagonal boron nitride is from 3 to 50 μm.

Typically, the composite material of the sheet and the sheet disclosed herein do not comprise a silicone.

The composite material of the sheet disclosed herein is obtained by densifying a material comprising a porous network of the polymer.

### First Process

A first process for producing the sheet as disclosed herein comprises
providing a polymer, a solvent, and hexagonal boron nitride particles comprising platelet-shaped hexagonal boron nitride particles;
combining the polymer, the solvent, and the hexagonal boron nitride particles to form a suspension of hexagonal boron nitride particles in a polymer-solvent solution; wherein the polymer in the polymer-solvent solution has a melting point, and wherein the solvent has a boiling point, and wherein combining the polymer, the solvent, and the hexagonal boron nitride particles is conducted at a temperature above the melting point of the polymer in the polymer-solvent solution, and below the boiling point of the solvent,
forming the suspension into a film, wherein the platelet-shaped hexagonal boron nitride particles are oriented in a direction parallel to the direction of the plane of the film;
inducing phase separation of the polymer from the solvent;
removing at least a portion of the solvent from the film to obtain a porous film;
optionally compressing the porous film to obtain a densified film;
stacking multiple layers either of the porous film or of the densified film one upon another to obtain a film stack;
pressing the film stack to obtain a bonded film stack; and
slicing a sheet from the bonded film stack in a direction perpendicular to the planes of the stacked film layers.

For producing the sheet as disclosed herein by the first process, polymers and hexagonal boron nitride particles as described above more in detail may be used.

The solvent is typically selected such that it is capable of dissolving the polymer and forming a polymer-solvent solution, i.e., the solvent needs to be miscible with the polymer [ok?] yes Heating the solution to an elevated temperature may facilitate the dissolution of the polymer. In some embodiments, combining the polymer and solvent is conducted at a temperature in a range from 20° C. to 350° C. The hexagonal boron nitride particles may be added at any or all of the combining, before the polymer is dissolved, after the polymer is dissolved, or at any time there between.

The solvent is selected such that it forms a polymer-solvent solution. The solvent may be a blend of at least two individual solvents. In some embodiments, when the polymer is a polyolefin (e.g., at least one of polyethylene and polypropylene), the solvent may be, for example, at least one of mineral oil, tetralin, decalin, orthodichlorobenzene, cyclohexane-toluene mixture, dodecane, paraffin oil/wax, kerosene, isoparaffinic fluids, p-xylene/cyclohexane mixture (1/1 wt./wt.), camphene, 1,2,4 trichlorobenzene, octane, orange oil, vegetable oil, castor oil, or palm kernel oil. In some embodiments, when the polymer is polyvinylidene fluoride, the solvent may be, for example, at least one of ethylene carbonate, propylene carbonate, or 1,2,3 tricetoxypropane.

The polymer, the solvent, and the hexagonal boron nitride particles may be combined using conventional mixing aggregates such as a twin screw extruder, planetary extruder, conical twin screw extruder, kneader, or industrial mixer such as but not limited to a double planetary mixer.

In some embodiments of the first process, the polymer in the polymer-solvent solution has a melting point, and the solvent has a boiling point, and combining the polymer, the solvent, and the hexagonal boron nitride particles may be conducted at a temperature above the melting point of the polymer in the polymer-solvent solution, and below the boiling point of the solvent. By combining the polymer, the solvent, and the hexagonal boron nitride particles, a suspension of hexagonal boron nitride particles in a polymer-solvent solution is formed.

After forming the suspension of hexagonal boron nitride particles in a polymer-solvent solution, the suspension is formed into a film. In the film, the platelet-shaped hexagonal boron nitride particles are oriented in a direction parallel to the direction of the plane of the film. The film may be a continuously formed film, or a film or layer comprising microreplicated or macroreplicated structures and made by microreplication or microreplication techniques. The forming of a film may be conducted using techniques known in the art, including, knife coating, roll coating (e.g., roll coating through a defined nip), and extrusion (e.g., extrusion through a die (e.g., extrusion through a die having the appropriate layer dimensions (i.e., width and thickness of the die gap))).

In one exemplary embodiment, the polymer-solvent solution has a paste-like consistency and is formed into the film by extrusion (e.g., extrusion through a die having the appropriate layer dimensions (i.e., width and thickness of the die gap)).

After forming the suspension into a film, where the polymer is miscible in its solvent, the polymer is then induced to phase separate. Several techniques may be used to induce phase separation, including at least one of thermally induced phase separation or solvent induced phase separation. Thermally induced phase separation may occur when the temperature at which induced phase separation is conducted is lower than the combining temperature of the polymer, solvent, and the hexagonal boron nitride particles. This may be achieved by cooling the polymer-solvent solution, if combining is conducted near room temperature, or by first heating the polymer-solvent solution to an elevated temperature (either during combining or after combining), followed by decreasing the temperature of the polymer-solvent solution, thereby inducing phase separation of the polymer. In both cases, the cooling may cause phase separation of the polymer from the solvent. Solvent induced phase separation can be conducted by adding a second solvent, a poor solvent for the polymer, to the polymer-solvent solution, or may be achieved by removing at least a portion of the solvent of the polymer-solvent solution (e.g., evaporating at least a portion of the solvent of the polymer-solvent solution), thereby inducing phase separation of the polymer. Combining of phase separation techniques (e.g., thermally induced phase separation and solvent induced phase separation), may be employed. Thermally induced phase separation may be advantageous, as it also facilitates the dissolution of the polymer when combining is conducted at an elevated temperature. In some embodiments, thermally inducing phase separation is conducted at a temperature in a range from 5 to 300 (in some embodiments, in a range from 5 to 250, 5 to 200, 5 to 150, 15 to 300, 15 to 250, 15 to 200, 15 to 130, or even 25 to 110)° C. below the combining temperature.

In some embodiments of the first process, the polymer in the polymer-solvent solution has a melting point, and the inducing phase separation is conducted at a temperature less than the melting point of the polymer in the polymer-solvent solution.

During the induced phase separation, a polymeric network structure may be formed. In some embodiments, the phase separation is induced thermally (e.g., via thermally induced phase separation (TIPS) by quenching to lower temperature), chemically (e.g., via solvent induced phase separation (SIPS) by substituting a poor solvent for a good solvent), or change in the solvent ratio (e.g., by evaporation of one of the solvents). Other phase separation or pore formation techniques known in the art, such as discontinuous polymer blends (also sometimes referred to as polymer assisted phase inversion (PAPI), moisture induced phase separation, or vapor induced phase separation, can also be used. The polymeric network structure may be inherently porous (i.e., have pores). The pore structure may be open, enabling fluid communication from an interior region of the polymeric network structure to an exterior surface of the polymeric network structure and/or between a first surface of the polymeric network structure and an opposing second surface of the polymeric network structure.

The polymeric network structure may be described as a porous polymeric network or a porous phase-separated polymeric network. Generally, the porous polymeric network (as-made) includes an interconnected porous polymeric network structure comprising a plurality of interconnected morphologies (e.g., at least one of fibrils, nodules, nodes, open cells, closed cells, leafy laces, strands, spheres, or honeycombs). The interconnected polymeric structures may adhere directly to the surface of the hexagonal boron nitride particles and act as a binder for the hexagonal boron nitride particles. In this regard, the space between adjacent hexagonal boron nitride particles (e.g., primary particles or agglomerates) may include porous polymeric network structures, as opposed to a solid matrix material.

In some embodiments, the polymeric network structure may include a 3-dimensional reticular structure that includes an interconnected network of polymeric fibrils, In some embodiments, individual fibrils have an average width in a range from 10 nm to 100 nm (in some embodiments, in a range from 100 nm to 500 nm, or even 500 nm to 5 micrometers).

In some embodiments, the hexagonal boron nitride particles are dispersed within the polymeric network structure, such that an external surface of the individual units of the hexagonal boron nitride particles (e.g., individual particles or individual agglomerate particles) is mostly uncontacted, or uncoated, by the polymeric network structure. In this regard, in some embodiments, the average percent areal coverage of the polymeric network structure on the external surface of the individual particles (i.e., the percent of the external surface area that is in direct contact with the polymeric network structure) is not greater than 50 (in some embodiments, not greater than 40, 30, 25, 20, 10, 5, or even not greater than 1) percent, based on the total surface area of the external surfaces of the individual particles. Although not wanting to be bound by theory, it is believed that the large, uncontacted surface area coating on the hexagonal boron nitride particles enables increased particle-to-particle contact upon compression and therefore increases thermal conductivity.

After the polymer has been phase separated from the solvent by the inducing phase separation step, at least a portion of the solvent may be removed from the film, i.e., from the polymeric network structure of the film, thereby forming a porous film. The porous film has a polymeric network structure and the hexagonal boron nitride particles are distributed within the polymeric network structure.

The solvent (e.g., a first solvent) may be removed by evaporation, high vapor pressure solvents being particularly suited to this method of removal. If the first solvent, however, has a low vapor pressure, it may be desirable to have a second solvent, of higher vapor pressure, to extract the first solvent, followed by evaporation of the second solvent. In some embodiments, in a range from 10 to 100 (in some embodiments, in a range from 20 to 100, 30 to 100, 40 to 100, 50 to 100, 60 to 100, 70 to 100, 80 to 100, 90 to 100, 95 to 100, or even 98 to 100) percent by weight of the solvent, and second solvent, if used, may be removed from the film.

For example, in some embodiments, when mineral oil is used as a first solvent, isopropanol at elevated temperature (e.g., about 60° C.) or a blend of methyl nonafluorobutyl ether (C₄F₉OCH₃), ethyl nonaflurorobutyl ether (C₄F₉OC₂H₅), and trans-1,2-dichloroethylene (available, for example, under the trade designation “NOVEC 72DE” from 3M Company, St. Paul, MN) may be used as a second solvent to extract the first solvent, followed by evaporation of the second solvent. In some embodiments, when at least one of vegetable oil or palm kernel oil is used as the first solvent, isopropanol at elevated temperature (e.g., about 60° C.) may be used as the second solvent. In some embodiments, when ethylene carbonate is used as the first solvent, water may be used as the second solvent.

In some embodiments of the first method, the formed and phase separated film, after the solvent removal, has a porosity of at least 5 (in some embodiments, at least 10, 20, 30, 35, 40, 45, 50, 55, 60, 65, 70, 75, or even at least 80; in some embodiments, in a range from 25 to 80) percent. This porosity is caused by the phase separation of the polymer from the solvent, which initially leaves no unfilled voids, as the pores in the polymeric network structure are filled with solvent. After the solvent is completely or partly removed, pores are formed in the polymeric network structure.

Typically, the polymer used in the first process disclosed herein is a thermoplastic polymer. The thickness of the porous film and of the densified film may be, e.g., from 5 to 150 mils (0.127 to 3.81 mm). The thickness of the porous film and of the densified film may also be lower than 5 mil or higher than 150 mil.

### Second Process

A second process for producing the sheet as disclosed herein comprises
providing a polymer, a solvent, and hexagonal boron nitride particles comprising platelet-shaped hexagonal boron nitride particles,
combining (e.g., mixing or blending) the polymer, the solvent, and the hexagonal boron nitride particles to form a slurry, wherein the slurry is a suspension of the polymer and the hexagonal boron nitride particles in the solvent, and wherein the polymer has a melting point, and wherein the solvent has a boiling point, and wherein combining the polymer, the solvent, and the hexagonal boron nitride particles is conducted below the melting point of the polymer, and below the boiling point of the solvent,
forming the slurry into a film, wherein the platelet-shaped hexagonal boron nitride particles are oriented in a direction parallel to the direction of the plane of the film,
heating the film in an environment to retain at least 90 (in some embodiments, at least 91, 92, 93, 94, 95, 96, 97, 98, 99, 99.5 or even 100) percent by weight of the solvent in the film, based on the weight of the solvent in the film, and solubilizing at least 50 (in some embodiments, at least 55, 60, 65, 70, 75, 80, 85, 90, 95, 96, 97, 98, 99, or even 100) percent by weight of the polymer in the solvent, based on the total weight of the polymer,
inducing phase separation of the polymer from the solvent,
removing at least a portion (in some embodiments, at least 50, 55, 60, 65, 70, 75, 80, 95, 96, 97, 98, 99, 99.5, or even 100 percent by weight of the solvent, based on the weight of the solvent in the film) of the solvent from the film to obtain a porous film,
optionally compressing the porous film to obtain a densified film,
stacking multiple layers either of the porous film or of the densified film one upon another to obtain a film stack,
pressing the film stack to obtain a bonded film stack, and
slicing a sheet from the bonded film stack in a direction perpendicular to the planes of the stacked film layers.

Typically, the polymer used in the second process disclosed herein is a thermoplastic polymer.

For producing the sheet as disclosed herein by the second process, polymers and hexagonal boron nitride particles as described above more in detail may be used.

The solvent is typically selected such that it is capable of dissolving the polymer and forming a polymer-solvent solution, i.e., the solvent needs to be miscible with the polymer. Heating the solution to an elevated temperature may facilitate the dissolution of the polymer. In some embodiments, combining the polymer and solvent is conducted at a temperature in a range from 20° C. to 350° C. The hexagonal boron nitride particles may be added at any or all of the combining, before the polymer is dissolved, after the polymer is dissolved, or at any time there between.

In some embodiments of the second process, the solvent is a blend of at least two individual solvents. In some embodiments, when the polymer is a polyolefin (e.g., at least one of polyethylene or polypropylene), the solvent may be at least one of mineral oil, tetralin, decalin, orthodichlorobenzene, cyclohexane-toluene mixture, dodecane, paraffine oil/wax, kerosene, p-xylene/cyclohexane mixture (1/1 wt./wt.), camphene, 1,2,4 trichlorobenzene, octane, orange oil, vegetable oil, castor oil, or palm kernel oil. In some embodiments, when the polymer is polyvinylidene fluoride, the solvent is at least one of ethylene carbonate, propylene carbonate, or 1,2,3 triacetoxypropane.

The slurry may be continuously mixed or blended to prevent or reduce settling or separation of the polymer and/or particles from the solvent. Typically, there is no need for continuously mixing or blending to prevent or reduce settling or separation of the polymer and/or particles from the solvent. In some embodiments, the slurry is degassed using techniques known in the art to remove entrapped air.

The slurry, which is obtained by combining (e.g., mixing or blending) the polymer, the solvent, and the hexagonal boron nitride particles, is a suspension of the polymer and the hexagonal boron nitride particles in the solvent.

The polymer, the solvent, and the hexagonal boron nitride particles may be combined using conventional mixing aggregates such as a twin screw extruder, planetary extruder, conical twin screw extruder, kneader, or industrial mixer such as but not limited to a double planetary mixer.

In some embodiments of the second process, the weight ratio of solvent to polymer is at least 9:1.

In some embodiments of the second process, combining is conducted at a temperature below the melting point of the polymer and below the boiling point of the solvent.

The polymer provided for the processes disclosed herein has a melting point, and the solvent has a boiling point. In some embodiments of the second process, combining the polymer, the solvent, and the hexagonal boron nitride particles is conducted at a temperature below the melting point of the polymer, and below the boiling point of the solvent. By combining the polymer, the solvent, and the hexagonal boron nitride particles, a slurry, i.e., a suspension of the polymer and hexagonal boron nitride particles in the solvent is formed.

The slurry is formed into a film using techniques known in the art, including knife coating, roll coating (e.g., roll coating through a defined nip), and coating through any number of different dies having the appropriate dimensions or profiles. These coating techniques may be performed between two liners.

In some embodiments, and for ease of manufacturing, it may be desirable to form the film at room temperature.

In some embodiments of the second process, heating the film is conducted at a temperature above the melting point of the miscible polymer-solvent solution, and below the boiling point of the solvent.

In some embodiments of the second process, inducing phase separation is conducted at a temperature less than the melting point of the polymer in the slurry. Although not wanting to be bound, it is believed that in some embodiments, solvents used to make a miscible blend with the polymer can cause melting point depression in the polymer. The melting point described herein includes below any melting point depression of the polymer solvent system.

The inducing phase separation is conducted at less than the melting point of the polymer.

During the induced phase separation, a polymeric network structure may be formed. In some embodiments, the phase separation is induced thermally (e.g., via thermally induced phase separation (TIPS) by quenching to lower temperature than used during heating). Cooling can be provided, for example, in air, liquid, or on a solid interface, and varied to control the phase separation. The polymeric network structure may be inherently porous (i.e., have pores). The pore structure may be open, enabling fluid communication from an interior region of the polymeric network structure to an exterior surface of the polymeric network structure and/or between a first surface of the polymeric network structure and an opposing second surface of the polymeric network structure.

The polymeric network structure may be described as a porous polymeric network or a porous phase-separated polymeric network. Generally, the porous polymeric network (as-made) includes an interconnected porous polymeric network structure comprising a plurality of interconnected morphologies (e.g., at least one of fibrils, nodules, nodes, open cells, closed cells, leafy laces, strands, spheres, or honeycombs). The interconnected polymeric structures may adhere directly to the surface of the hexagonal boron nitride particles and act as a binder for the hexagonal boron nitride particles. In this regard, the space between adjacent hexagonal boron nitride particles (e.g., primary particles or agglomerates) may include porous polymeric network structures, as opposed to a solid matrix material.

The polymeric network structure may comprise a plurality of nodes which are interconnected by a plurality of fibrils. Typically, the nodes have a diameter of from 1 to 50 μm. The diameter is measured as the maximum diameter on scanning electron micrographs of the composite material. The fibrils which connect the individual nodes with one another may have a diameter of from 80 to 2000 nm and a length of from 1 to 50 μm. The nodes and the fibrils comprise the polymer. The nodes and the fibrils may consist of the polymer. The hexagonal boron nitride particles may be located near the nodes or within the nodes. The hexagonal boron nitride particles may also be located near the fibrils or may be connected to the fibrils. The fibrils may be mechanically anchored to the hexagonal boron nitride particles, or, in other words, the hexagonal boron nitride particles may act as nodes to which the fibrils are mechanically anchored. The porosity of the composite material results from pores that are located between the fibrils. The fibrils of the composite material comprised in the sheet disclosed herein are different from fibers as known in the art. Fibers are a possible macroscopic shape of a material and typically have a length of at least 100 μm, e.g., at least 1 mm and up to 30 mm and a plurality of fibers may be comprised in a non-homogeneous woven or braided structure. In contrast, the fibrils of the composite material comprised in the sheet disclosed herein are microscopic structures with typical diameters of 80 to 2000 nm (e.g., 80 to 800 nm) and lengths of 1 to 50 μm, and with each of the fibrils being interconnected with the nodes.

In some embodiments, the polymeric network structure may include a 3-dimensional reticular structure that includes an interconnected network of polymeric fibrils, In some embodiments, individual fibrils have an average width in a range from 10 nm to 100 nm (in some embodiments, in a range from 100 nm to 500 nm, or even 500 nm to 5 micrometers).

In some embodiments, the hexagonal boron nitride particles are dispersed within the polymeric network structure, such that an external surface of the individual units of the hexagonal boron nitride particles (e.g., individual particles or individual agglomerate particles) is mostly uncontacted, or uncoated, by the polymeric network structure. In this regard, in some embodiments, the average percent areal coverage of the polymeric network structure on the external surface of the individual particles (i.e., the percent of the external surface area that is in direct contact with the polymeric network structure) is not greater than 50 (in some embodiments, not greater than 40, 30, 25, 20, 10, 5, or even not greater than 1) percent, based on the total surface area of the external surfaces of the individual particles. Although not wanting to be bound by theory, it is believed that the large, uncontacted surface area coating on the hexagonal boron nitride particles enables increased particle-to-particle contact upon compression and therefore increases thermal conductivity.

After the phase separation, at least a portion of the solvent is removed from the film. By removing at least a portion of the solvent from the film, a porous film is obtained. In some embodiments of the second process, at least 90 percent by weight of the solvent, based on the weight of the solvent in the film, is removed. The film, before removing at least 90 percent by weight of the solvent, based on the weight of the solvent in the film, has a first volume, and the film, after removing at least 90 percent by weight of the solvent, based on the weight of the solvent in the film, has a second volume, and the difference between the first and second volume (i.e., (the first volume minus the second volume) divided by the first volume times 100) is less 10 (in some embodiments, less than 9, 8, 7, 6, 5, 4, 3, 2, 1, 0.75, 0.5, or even less than 0.3) percent. Volatile solvents can be removed from the film, for example, by allowing the solvent to evaporate from at least one major surface of the film. Evaporation can be aided, for example, by the addition of at least one of heat, vacuum, or air flow. Evaporation of flammable solvents can be achieved in a solvent-rated oven. If the solvent (i.e., a first solvent), however, has a low vapor pressure, a second solvent, of higher vapor pressure, may be used to extract the first solvent, followed by evaporation of the second solvent. For example, in some embodiments, when mineral oil is used as a first solvent, isopropanol at elevated temperature (e.g., about 60° C.) or a blend of methyl nonafluorobutyl ether (C₄F₉OCH₃), ethylnonafluorobutyl ether (C₄F₉OC₂H₅), and trans-1,2-dichloroethylene (available, for example, under the trade designation “NOVEC 72E” from 3M Company, St. Paul, MN) may be used as a second solvent to extract the first solvent, followed by evaporation of the second solvent. In some embodiments, when at least one of vegetable oil or palm kernel oil is used as the first solvent, isopropanol at elevated temperature (e.g., about 60° C.) may be used as the second solvent. In some embodiments, when ethylene carbonate is used as the first solvent, water may be used as the second solvent.

In some embodiments of the second method, the film has a first and second major surface with ends perpendicular to the first and second major surfaces, and the ends are unrestrained during the solvent removal. This can be done, for example, by drying a portion of a layer without restraint in an oven. Continuous drying can be achieved, for example, by drying a long portion of a layer, supported on a belt as it is conveyed through an oven. Alternatively, to facilitate removal of non-volatile solvent, for example, a long portion of the film can be continuously conveyed through a bath of compatible volatile solvent, thereby exchanging the solvents and allowing the film to be subsequently dried without restraint. Not all the non-volatile solvent, however, needs to be removed from the film during the solvent exchange. Small amounts of non-volatile solvents may remain and act as a plasticizer to the polymer.

In some embodiments of the second method, the formed and phase separated film, after the solvent removal, has a porosity of at least 5 (in some embodiments, at least 10, 20, 30, 35, 40, 45, 50, 55, 60, 65, 70, 75, or even at least 80; in some embodiments, in a range from 25 to 80) percent. This porosity is caused by the phase separation of the polymer from the solvent, which initially leaves no unfilled voids, as the pores in the polymeric network structure are filled with solvent. After the solvent is completely or partly removed, pores are formed in the polymeric network structure. In some embodiments of the first and second process, up to 10 percent by weight of non-volatile solvents or organic liquids remain in the porous film after solvent removal, improving the elasticity of the porous film and of the sheet made from the porous film. It is also possible that up to 10 percent by weight of non-volatile organic liquids are added after solvent removal. The first and the second process optionally include compressing the porous film, after removing at least a portion of the solvent from the film. By compressing the porous film, the porous film is densified. Compressing the porous film may be achieved, for example, by conventional calendering processes known in the art.

By compressing the porous film, the polymeric network structure of the porous film is plastically deformed. Vibratory energy may be imparted during the application of the compressive force. In some embodiments, the porous film is in the form of a strip of indefinite length, and the applying of a compressive force step is performed as the strip passes through a nip. A tensile loading may be applied during passage through a nip. For example, the nip may be formed between two rollers, at least one of which applies the vibratory energy; between a roller and a bar, at least one of which applies the vibratory energy; or between two bars, at least one of which applies the vibratory energy. The applying of the compressive force and the vibratory energy may be accomplished in a continuous roll-to-roll fashion, or in a step-and-repeat fashion. In other embodiments, the applying a compressive force step is performed on a discrete layer between, for example, a plate and a platen, at least one of which applies the vibratory energy. In some embodiments, the vibratory energy is in the ultrasonic range (e.g., 20 kHz), but other ranges are considered to be suitable.

The density of the densified film may be at least 60% (in some embodiments, at least 70%, at least 80%, at least 90%, or even 100%; in some embodiments, in the range from 60 to 98%, 70 to 98%, 80 to 98%, 60 to 100%, 70 to 100%, or even 80 to 100%) of theoretical density after densification. The theoretical density can be calculated from the known densities of the components of the densified porous film and from the weight fractions of the components.

By compressing the porous film, the density and the thermal conductivity of the film is increased by increasing the particle-to-particle contact of the hexagonal boron nitride particles. Compression of the porous film increases the density, which reduces the insulating air volume (or porosity) of the film, which will therefore increase the thermal conductivity. Likewise, the increased particle-to-particle contact of the hexagonal boron nitride particles can be measured by increased thermal conductivity.

By compression of the porous polymeric network structure of the film, a film having a higher density and a compressed polymeric network structure is obtained, with the hexagonal boron nitride particles distributed within the polymer network and with increased particle-to-particle contact.

If the porous film is not compressed before stacking multiple layers, the density and the thermal conductivity is increased by pressing the film stack, which compresses the porous polymeric network structure of the film. By pressing the film stack, the particle-to-particle contact of the hexagonal boron nitride particles is increased.

The through-plane thermal conductivity of the uncompressed porous film may be in the range from 0.2 to 0.8 W/m*K, and the in-plane thermal conductivity of the uncompressed porous film may be from 0.80 to 2.0 W/m*K. The through-plane thermal conductivity of the compressed, densified film may be in a range from 0.80 to 3.5 W/m*K, and the in-plane thermal conductivity of the compressed, densified film may be from 4.0 to 45 W/m*K.

The processes for producing the sheet as disclosed herein, i.e., the first and the second process, comprise stacking multiple layers either of the porous film or of the densified film one upon another. If the porous film has not been densified before stacking, multiple layers of the porous film are stacked one upon another. If the porous film has been densified before stacking, multiple layers of the densified film are stacked one upon another. By stacking multiple layers, either of the porous film or of the densified film, a film stack is obtained.

For stacking multiple layers of the porous film, or of the densified film, respectively, the porous film, or the densified film, respectively, may be cut into film pieces of equal size and the film pieces may be stacked.

Pressing the film stack for the first and the second process is performed at a pressure and at a temperature and for a time sufficient to ensure bonding of the individual film layers to a bonded film stack, i.e., to a bonded block.

Pressing the film stack for the first and second process may be performed at a temperature of at least 110° F. (43° C.) and typically is performed at a temperature of at most 575° F. (302° C.). For example, if the polymer used to make the composite material of the sheet disclosed herein is an ultra-high molecular weight polyethylene, pressing the film stack may be performed at a temperature of at least 275° F. (135° C.) and typically is performed at a temperature of at most 400° F. (204° C.). By this pressing step, a bonded film stack is obtained.

It has been found that a minimum pressing pressure is required for pressing the film stack.

Advantageously, pressing the film stack may be performed under a pressing pressure of at least 2.0 MPa. By using a pressing pressure of at least 2.0 MPa, it is ensured that the individual layers of the film stack are bonded to one another and a bonded film stack, i.e., a bonded block, is obtained. In the bonded block, the individual film layers are seamlessly bonded to one another.

Furthermore, it has been found that, by further increasing the pressing pressure to values higher than the minimum pressing pressure of 2.0 MPa, through-plane thermal conductivity of the sheet obtained after the subsequent slicing step can be significantly further increased. Without wishing to be bound by theory, it is believed that this can be explained by an increased particle-to-particle contact of the hexagonal boron nitride particles from layer to layer, i.e., between originally individual adjacent film layers in the bonded film stack formed upon pressing. Typically, pressing the film stack is performed under a pressing pressure of up to 40 MPa. Higher pressing pressures are possible, but are typically not required, as the through-plane thermal conductivity of the sheet typically is not further increased by increasing pressing pressure above 40 MPa.

Typically, pressing the film stack is performed for at least 2 minutes.

Advantageously, pressing the film stack may be performed in a pressing direction (i.e., in z-direction) while the film stack is constrained in a first and in a second direction perpendicular to the pressing direction, wherein the first direction is perpendicular to the second direction (i.e., in x- and y-direction). For example, a mold, e.g., a steel mold, may be used to constrain the stack in x- and y-direction. Another possibility is to perform pressing of the film stack in a pressing direction (i.e., in z-direction) while constraining the film stack in a first direction perpendicular to the pressing direction (i.e., in x-direction) and allowing the film stack to expand in a second direction perpendicular to the pressing direction, wherein the first direction is perpendicular to the second direction (i.e., in the y-direction).

The x-direction, or first direction perpendicular to the pressing direction, is a first direction parallel to the planes of the multiple layers of the porous or densified film. The y-direction, or second direction perpendicular to the pressing direction, is a second direction parallel to the planes of the multiple layers of the porous or densified film. The z-direction, or pressing direction, is a direction perpendicular to the planes of the multiple layers of the porous or densified film.

The processes as disclosed herein for producing the sheet of the present disclosure, i.e., the first and second process, may further comprise
heating the film stack prior to pressing the film stack.

Advantageously, the film stack may be heated to a temperature from 110° F. to 575° F. (43° C. to 302° C.) prior to pressing the film stack. The temperature to be selected typically is near or above the melting temperature of the polymer binder. For example, if the polymer used to make the composite material of the sheet disclosed herein is an ultra-high molecular weight polyethylene, the film stack may be heated to a temperature from 275° F. to 400° F. (135° C. to 204° C.) prior to pressing the film stack.

By heating the film stack prior to pressing the film stack, a better bonding between the individual stacked film layers can be obtained.

The first and second process comprises slicing a sheet from the bonded film stack in a direction perpendicular to the planes of the stacked film layers.

Slicing (or cutting) may be performed by using a skiving knife. A pneumatic cylinder may be used to force the bonded film stack across the knife. The bonded film stack may be heated to make cutting easier. Force may also be applied to keep the bonded film stack pressed down against the knife.

The sheet obtained by the first and second process comprises a composite material comprising a polymer and platelet-shaped hexagonal boron nitride particles, wherein the platelet-shaped hexagonal boron nitride particles are oriented in a direction perpendicular to the direction of the plane of the sheet. By the orientation of the platelet-shaped hexagonal boron nitride particles in a direction perpendicular to the direction of the plane of the sheet, and by the high loadings of hexagonal boron nitride particles in the composite material, a sheet having a high through-plane thermal conductivity can be obtained.

The processes as disclosed herein for producing the sheet of the present disclosure, i.e., the first and second process, may further comprise heating of the bonded film stack prior to slicing a sheet from the bonded film stack.

Advantageously, the bonded film stack may be heated to a temperature from 110° F. to 575° F. (43° C. to 302° C.) prior to slicing a sheet from the bonded film stack. The temperature to be selected typically is near or above the melting temperature of the polymer binder. For example, if the polymer used to make the composite material of the sheet disclosed herein is an ultra-high molecular weight polyethylene, the bonded film stack may be heated to a temperature from 275° F. to 400° F. (135° C. to 204° C.) prior to slicing a sheet from the bonded film stack.

By heating the bonded film stack prior to slicing a sheet from the bonded film stack, the bonded film stack is softened which makes slicing easier.

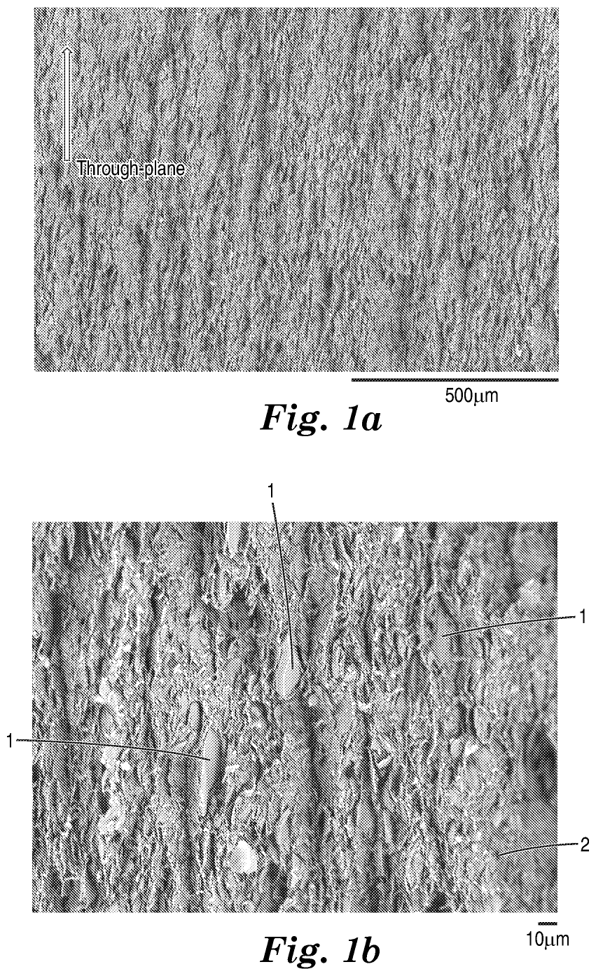

FIGS. 1a and 1b show scanning electron micrographs (SEM) of a cross-section of the sheet as disclosed herein. FIG. 1b is a detail of Figure la with enlarged magnification. In FIG. 1b, platelet-shaped hexagonal boron nitride particles 1 are distributed in the sheet in a network of a polymer material 2. The platelet-shaped hexagonal boron nitride particles 1 have an orientation perpendicular to the direction of the plane of the sheet. The direction perpendicular to the direction of the plane of the sheet is indicated in FIG. 1a by the white arrow (through-plane direction).

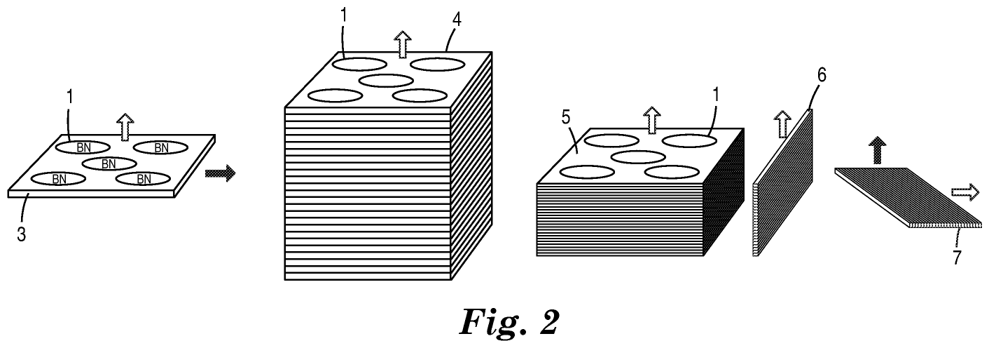

In FIG. 2, the stacking of multiple layers of the densified film one upon another to obtain a film stack, and the slicing of a sheet from the bonded film stack in a direction perpendicular to the planes of the stacked film layers is represented schematically. In a first step of the processes disclosed herein, a porous film 3 is formed comprising platelet-shaped hexagonal boron nitride particles 1 which are oriented in a direction parallel to the direction of the plane of the film. In an optional process step, the porous film may be densified to obtain a densified film. The white arrows in FIG. 2 represent the direction perpendicular to the basal planes of the hexagonal boron nitride particles, the black arrows in FIG. 2 represent the direction parallel to the basal planes of the hexagonal boron nitride particles. In the drawing for the single film layer 3 (porous or densified) on the left side of FIG. 2, the white arrow (representing the direction perpendicular to the basal planes of the hexagonal boron nitride particles, which is the direction of low thermal conductivity) is oriented perpendicularly to the direction of the plane of the film, i.e., in a direction through-plane of the film. The black arrow (representing the direction parallel to the basal planes of the hexagonal boron nitride particles, which is the direction of high thermal conductivity) is oriented parallelly to the direction of the plane of the film, i.e., in a direction in-plane of the film. In a further step of the processes disclosed herein, multiple layers of the porous or densified film 3 are stacked one upon another to obtain a film stack 4. In the drawing of the film stack 4 of FIG. 2, the white arrow (representing the direction perpendicular to the basal planes of the hexagonal boron nitride particles, which is the direction of low thermal conductivity) is oriented perpendicularly to the direction of the planes of the multiple layers of the porous or densified film. In the next step of the processes disclosed herein, the film stack 4 is pressed to obtain a bonded film stack 5. From the bonded film stack 5, a sheet 6 is sliced in a direction perpendicular to the planes of the stacked film layers. In the drawing of the sheet 7 on the right side of FIG. 2, the sheet 6 which had been obtained by the slicing step is rotated by 90 degrees so that the direction of the plane of the obtained sheet is now parallel to the plane of the drawing. In this drawing of the sheet 7, the white arrow (representing the direction perpendicular to the basal planes of the hexagonal boron nitride particles, which is the direction of low thermal conductivity) is oriented parallelly to the direction of the plane of the sheet, i.e., in a direction in-plane of the sheet. The black arrow (representing the direction parallel to the basal planes of the hexagonal boron nitride particles, which is the direction of high thermal conductivity) is oriented perpendicularly to the direction of the plane of the sheet, i.e., in a direction through-plane of the sheet.

The sheet as disclosed herein is useful as thermal interface material. Such thermal interface materials are useful for managing heat flow into or out of different components such as in electronic devices (e.g., batteries, motors, refrigerators, circuit boards, solar cells, and heaters). In some embodiments, an article (e.g., electronic device) comprises a heat source and the sheet described herein in contact with the heat source.

### EXEMPLARY EMBODIMENTS

1A. A sheet comprising a composite material comprising a polymer and hexagonal boron nitride particles, wherein the hexagonal boron nitride particles comprise platelet-shaped hexagonal boron nitride particles, and wherein the platelet-shaped hexagonal boron nitride particles are oriented in a direction perpendicular to the direction of the plane of the sheet, and wherein the composite material comprises at least 70 percent by weight of the hexagonal boron nitride particles, based on the total weight of the composite material, and wherein the sheet has a through-plane thermal conductivity of more than 12 W/m*K.

2A. The sheet of Exemplary Embodiment 1A, wherein the composite material is obtained by densifying a material comprising a porous network of the polymer.

3A. The sheet of any preceding A Exemplary Embodiment, wherein the composite material comprises at least 80 percent by weight, preferably at least 85 percent by weight, more preferably at least 90 percent by weight, more preferably more than 90 percent by weight of the hexagonal boron nitride particles, based on the total weight of the composite material.

4A. The sheet of any preceding A Exemplary Embodiment, wherein the sheet has a through-plane thermal conductivity of at least 15 W/m*K.

5A. The sheet of any preceding A Exemplary Embodiment, wherein the composite material is electrically insulating.

6A. The sheet of any preceding A Exemplary Embodiment, wherein the orientation index of the sheet is greater than 4.0.

7A. The sheet of any preceding A Exemplary Embodiment, wherein the mean particle size (d₅₀) of the hexagonal boron nitride particles is from 0.5 to 500 μm.

8A. The sheet of any preceding A Exemplary Embodiment, wherein the hexagonal boron nitride particles comprise agglomerates of primary particles of hexagonal boron nitride, and wherein the primary particles comprise platelet-shaped hexagonal boron nitride particles, and wherein the mean particle size (d₅₀) of the agglomerates is from 30 to 500 μm.

9A. The sheet of Exemplary Embodiment 8A, wherein the mean particle size (d₅₀) of the primary particles of hexagonal boron nitride is from 3 to 50 μm.

10A. The sheet of any preceding A Exemplary Embodiment, wherein the hexagonal boron nitride particles comprise non-agglomerated platelet-shaped hexagonal boron nitride particles having a mean particle size (d₅₀) of from 3 to 100 μm, preferably from 5 to 30 μm.

11A. The sheet of any preceding A Exemplary Embodiment, wherein the aspect ratio of the platelet-shaped hexagonal boron nitride particles is at least 5.

12A. The sheet of any preceding A Exemplary Embodiment, wherein the composite material comprises at least 80 percent by weight and up to 98 percent by weight of the hexagonal boron nitride particles, based on the total weight of the composite material.

13A. The sheet of any preceding A Exemplary Embodiment, wherein the composite material comprises at least 2 percent by weight and at most 20 percent by weight of the polymer, based on the total weight of the composite material.

14A. The sheet of any preceding A Exemplary Embodiment, wherein the composite material further comprises 0.1 to 10 percent by weight of mineral oil, based on the total weight of the composite material.

15A. The sheet of any preceding A Exemplary Embodiment, wherein the polymer is selected from the group consisting of polyurethane, polyester, polyamide, polyether, polycarbonate, polyimide, polysulfone, polyethersulfone, polyphenylene oxide, polyacrylate, polymethacrylate, polyacrylonitrile, polyolefin, styrene, styrene-based copolymer, styrene-base copolymer, chlorinated polymer, fluorinated polymer, copolymers of ethylene and chlorotrifluoroethylene, and combinations thereof.

16A. The sheet of any preceding A Exemplary Embodiment, wherein the polymer is an ultra-high molecular weight polyethylene having a number average molecular weight in a range from 5×10⁴ to 1×10⁷ g/mol.

17A. The sheet of any preceding A Exemplary Embodiment, wherein the composite material has a porosity of up to 40%.

18A. The sheet of any preceding A Exemplary Embodiment, wherein the composite material has a porosity of from 0.5 to 40%.

19A. The sheet of any preceding A Exemplary Embodiment, wherein the composite material has a porosity of from 2 to 30%.

20A. The sheet of any preceding A Exemplary Embodiment, wherein the sheet has a dielectric dissipation factor of less than 0.009 at 5.2 GHz.

21A. The sheet of any preceding A Exemplary Embodiment, wherein the sheet has a dielectric constant of at most 5.0 at 5.2 GHz.

22A. The sheet of any preceding A Exemplary Embodiment, wherein the through-plane thermal conductivity of the sheet is higher than the in-plane thermal conductivity of the sheet.

23A. The sheet of any preceding A Exemplary Embodiment, wherein the composite material does not comprise fibers.

24A. The sheet of any preceding A Exemplary Embodiment, wherein the sheet has a Shore D hardness of 30 to 150.

25A. The sheet of any preceding A Exemplary Embodiment, wherein the sheet has a thickness of from 0.01 mm to 6 mm.

1B. A process for producing a sheet of any preceding A Exemplary Embodiment, the process comprising
providing a polymer, a solvent, and hexagonal boron nitride particles comprising platelet-shaped hexagonal boron nitride particles,
combining the polymer, the solvent, and the hexagonal boron nitride particles to form a suspension of hexagonal boron nitride particles in a polymer-solvent solution, wherein the polymer in the polymer-solvent solution has a melting point, and wherein the solvent has a boiling point, and wherein combining the polymer, the solvent, and the hexagonal boron nitride particles is conducted at a temperature above the melting point of the polymer in the polymer-solvent solution, and below the boiling point of the solvent,
forming the suspension into a film, wherein the platelet-shaped hexagonal boron nitride particles are oriented in a direction parallel to the direction of the plane of the film,
inducing phase separation of the polymer from the solvent,
removing at least a portion of the solvent from the film to obtain a porous film,
optionally compressing the porous film to obtain a densified film,
stacking multiple layers either of the porous film or of the densified film one upon another to obtain a film stack,
pressing the film stack to obtain a bonded film stack, and
slicing a sheet from the bonded film stack in a direction perpendicular to the planes of the stacked film layers.

2B. A process for producing a sheet of any preceding A Exemplary Embodiment, the process comprising
providing a polymer, a solvent, and hexagonal boron nitride particles comprising platelet-shaped hexagonal boron nitride particles,
combining the polymer, the solvent, and the hexagonal boron nitride particles to form a slurry, wherein the slurry is a suspension of the polymer and the hexagonal boron nitride particles in the solvent, and wherein the polymer has a melting point, and wherein the solvent has a boiling point, and wherein combining the polymer, the solvent, and the hexagonal boron nitride particles is conducted below the melting point of the polymer, and below the boiling point of the solvent,
forming the slurry into a film, wherein the platelet-shaped hexagonal boron nitride particles are oriented in a direction parallel to the direction of the plane of the film,
heating the film in an environment to retain at least 90 percent by weight of the solvent in the film, based on the weight of the solvent in the film, and solubilizing at least 50 percent by weight of the polymer in the solvent, based on the total weight of the polymer,
inducing phase separation of the polymer from the solvent,
removing at least a portion of the solvent from the film to obtain a porous film,
optionally compressing the porous film to obtain a densified film,
stacking multiple layers either of the porous film or of the densified film one upon another to obtain a film stack,
pressing the film stack to obtain a bonded film stack, and
slicing a sheet from the bonded film stack in a direction perpendicular to the planes of the stacked film layers.

3B. The process of Exemplary Embodiment 1B or of Exemplary Embodiment 2B, wherein the polymer has a melting point, and wherein the inducing phase separation is conducted at less than the melting point of the polymer.

4B. The process of any preceding B Exemplary Embodiment, further comprising
heating the film stack prior to pressing the film stack.

5B. The process of any preceding B Exemplary Embodiment, wherein pressing the film stack is performed at a temperature of at least 110° F.

6B. The process of any preceding B Exemplary Embodiment, further comprising heating of the bonded film stack prior to slicing a sheet from the bonded film stack.

7B. The process of any preceding B Exemplary Embodiment, wherein pressing the film stack is performed under a pressing pressure of at least 2.0 MPa.

8B. The process of any preceding B Exemplary Embodiment, wherein pressing the film stack is performed in a pressing direction while constraining the film stack in a first direction perpendicular to the pressing direction. 9B. The process of any preceding B Exemplary Embodiment, wherein pressing the film stack is performed in a pressing direction while constraining the film stack in a first direction perpendicular to the pressing direction and in a second direction perpendicular to the pressing direction, and wherein the first direction is perpendicular to the second direction.

### EXAMPLES

### Test Methods

### Air Flow Resistance Test

Air flow resistance was measured using a densometer (obtained as Model 4110 from Gurley Precision Instruments, Troy, NY, US) with a timer (obtained as Model 4320 from Gurley Precision Instruments). A sample was clamped in the tester. The timer and photo eye were reset and the cylinder was released, allowing air to pass through a 1 square inch (6.5 cm2) circle with a constant force of 4.88 inches (12.4 cm) of water (1215 N/m2). The time to pass 50 cm³ of air was recorded.

### Bubble Point Pressure Test

Bubble point pressure is a commonly used technique to characterize the largest pore in a porous membrane. Discs 47 mm in diameter were cut and samples soaked in 100% isopropyl alcohol (IPA) to fully fill and wet out the pores within the sample. The wet samples were then placed in a holder (47 mm Stainless Holder Part #2220 from Pall Corporation, Port Washington, NY, US). Pressure was slowly increased on the top of the sample using a pressure controller and gas flow was measured on the bottom with a gas flow meter. The pressure was recorded when there was a significant increase in flow from the baseline flow rate. This was reported as the bubble point pressure (pounds per square inch, psi). This technique is a modification to ASTM F316-03 (2006), “Standard Test Methods for Pore Size Characteristics of Membrane Filters by Bubble Point and Mean Flow Pore Test,” and includes an automated pressure controller and flow meter to quantify when the bubble point pressure has been reached. The pore size was calculated per the ASTM using the following equation:

$$Limiting Pore Diameter ( µm ) = ( Surface Tension in dynes / cm * 0.415 ) / ( Pressure in psi )$$

The factor of 0.415 was included since the pressure was in units of psi. A surface tension of 21.7 dynes/cm was used for the 100% isopropyl alcohol.

### Density and Porosity Test

If not otherwise indicated, the density of a sample was calculated using a method similar to ASTM F-1315-17 (2017), “Standard Test Method for Density of a Sheet Gasket Material” by cutting a 47 mm diameter disc, weighing the disc on an analytical balance of suitable resolution (typically 0.0001 grams), and measuring the thickness of the disc on a thickness gauge (obtained as Model 49-70 from Testing Machines, Inc., New Castle, DE, US) with a dead weight of 7.3 psi (50.3 KPa) and a flat anvil of 0.63 inch (1.6 cm) diameter, with a dwell time of about 3 seconds and a resolution of +/−0.0001 inch. The density was then calculated by dividing the mass by the volume, which was calculated from the thickness and diameter of the sample. With the known densities and weight fractions of the components of the composite material, the theoretical density of the composite material was calculated by the rule of mixtures. Using the theoretical density and the measured density, the porosity was calculated as:

$$Porosity = [ 1 - ( measured density / theoretical density ) ] \times 100$$

For some of the samples, the density was measured using the Archimedes density method due to uneven surfaces from bandsaw cutting. Density for these samples was measured using an analytical scale (obtained as model MS1003TS-C012187274 from Mettler Toledo (Schweiz) GmbH, Im Langacher 44, 8608 Griefensee, Switzerland). A glass container (similar to a beaker) was placed above the scale and was filled with distilled water until at least ¾ full. A sample dish with a basket attached to the bottom was placed above the glass container so that the basket was fully submerged, and where both the dish and basket are attached to the scale so their mass is measured. The scale's mass was zeroed and a roughly 1″×1″×½″ sample was placed in the top dish so that its mass in air was measured. After storing this data, the sample was placed in the basket below the dish so that the mass of the sample when submerged in water could be measured. Using the difference in mass between the sample when dry and when submerged in water, as well as 0.99777 g/cm³ for the density of distilled water at 22° C., the density of the block was calculated.

### Thermal Conductivity Test

Direct thermal diffusivity measurements are made using the flash analysis method as per ASTM E1461 (2013), using a light flash thermophysical properties analyzer (obtained as “HYPERFLASH LFA 467” from Netzsch Instruments North America LLC, Boston, MA, US). Each sample set included a reference sample (obtained under the trade designation “AXM-5Q POCO GRAPHITE” from Poco Graphite, Decatur, TX, US) which acted as a method control for diffusivity measurements. Samples are coated with a layer of sprayed-on graphite (3 spray passes at a distance of approximately 5 inches with graphite spray obtained under the trade designation “DGF 123 DRY GRAPHITE FILM SPRAY” from Miracle Power Products Corporation, Cleveland, OH, US) on the light impingement side and the detection side to normalize surface effusivity and absorptivity for the sample being tested. The sample's thickness was measured with a hand caliper (Fisher Scientific) in 5 different areas of the sample disc and the average of these measurements was calculated. The thickness was used to calculate the geometric density of the samples. In a single measurement, called a “shot”, a short time duration pulse of light (Xenon flash lamp, 230 V, 15 microsecond duration) was impinged onto one side of a sample, and a thermogram (time trace of measured temperature) was recorded on the opposite side of the sample, as measured by the voltage on an InSb IR detector. Thermal diffusivity was calculated from a fit of the thermogram to the Cowan Plus Pulse Correction model for through-plane and an anisotropic model for in-plane (the anisotropic model used for in-plane thermal diffusivity takes into account the through-plane data). Heat capacity was calculated by differential scanning calorimetry (DSC) using a DSC instrument (obtained under the trade designation “Q2000 DSC” from TA Instruments, New Castle, DE, US), following ASTM E1269 (2011) “Quasi-Isothermal Moderated DSC”. Sapphire was used as a reference for DSC. The through-plane diffusivity was calculated using the Cowan method with an additional correction for a finite pulse width, while in-plane diffusivity used the anisotropic model with the aid of the software (obtained under the trade designation “Proteus” from Netzsch, Selb, Germany). Samples with 1 inch diameter were used for the measurements. Three shots were obtained for each sample at 25° C. The product of measured density (p) (geometric from 2.54 cm (1 inch) discs), specific heat capacity (c_{P}) (by differential scanning calorimetry), and diffusivity (a) gave the thermal conductivity. That is,

$$k ( W / ( m * K ) ) = ρ ( g / cm 3 ) \times {c}_{P} ( J / K / g ) \times α ( {mm}^{2} / s ) .$$

Hardness Measurement (Shore D) The Shore durometer hardness of samples was measured according to ASTM D2240-15 using the D scale. Testing was performed under ambient lab conditions of 23° C. and less than 20% relative humidity. Measurements reported were from stacked, bonded blocks and reported as averages of four measurements for the skived surfaces parallel to the lamination plane.

### Dielectric Properties Measurement (Split-Post Dielectric Resonator Measurements at 5.2 GHz)

All dielectric properties were measured using a split-post dielectric resonator (SPDR) at 5.2 GHz per the IEC 61189-2-712 standard. Each 1 mm-thick sample was inserted between two fixed dielectric resonators. The resonance frequency and quality factor of the posts are influenced by the presence of the specimen, and this enables the direct computation of complex permittivity (dielectric constant and dielectric loss). The geometry of the split dielectric resonator fixture used in the measurements was built at and purchased from QWED in Warsaw, Poland, in collaboration with the Warsaw University of Technology under Professor Jerzy Krupka. This 5.2 GHz resonator operates with the TE01 delta mode, which has only an azimuthal electric field component that remains continuous on the dielectric interfaces. The split post dielectric resonator measures the permittivity within the plane of the specimen. Loop coupling (critically coupled) was used in each of these dielectric resonator measurements. This 5.2 GHz SPDR measurement system was combined with Keysight VNA (Vector Network Analyzer Model PNA 8364C 10 MHz-50 GHz). Computations were performed with the commercial analysis software built by Professor Jerzy Krupka and facilitated by Keysight's N1500A dielectric measurement software suite. Orientation index measurement The orientation index is determined by X-ray diffractometry. For this, the ratio of the intensities of the (100) and of the (002) reflection of hexagonal boron nitride (hBN) measured on X-ray diffraction diagrams of a sheet sample is determined and is divided by the corresponding ratio for an ideal, unoriented, i.e., isotropic, hBN sample. This ideal intensity ratio, or reference intensity ratio, can be determined from Powder Diffraction Pattern (PDF) #01-073-2095 of the International Centre for Diffraction Data (ICDD) data (2020) and is 0.147. The theoretical peak positions of (002) and (100) reflections are at 26.7 and 41.6 degrees, respectively. Peak intensities of (002) and (100) reflections are measured from peak area at these positions.

For measurement of peak intensities of (002) and (100) reflections, the samples were cut and loaded on zero background silicon sample holders. Reflection geometry data were collected in the form of a survey scan by use of a PANalytical Empyrean vertical diffractometer, copper Ka radiation, and PIXcel-3D detector (1D mode with 255 channels or 3.35° opening) registry of the scattered radiation. The X-ray source and detector are sitting at a circle with a radius of 240.00 mm. The diffractometer is fitted with 0.04 rad sollers at both incidence and diffraction beam sides, mask 20 and Ni filter on incidence side, programmable divergence slit at 140.00 mm sample distance to control irradiated length at the sample to 5.0 mm, receiving slit at height of 2.00 mm, and programmable anti-scatter slit to control observed length to 2.0 mm. The survey scan was conducted from 5 to 80 degrees (2q) using a 0.04 degree step size and 1200-second setting for dwell time. X-ray generator settings of 40 kV and 40 mA were employed.

The orientation index (OI) can be determined from the measured peak intensities of (002) and (100) reflections using the formula:

$$O I = \frac{{I}_{( 1 \; 00 ) , sample} / {I}_{( 0 \; 02 ) , sample}}{{I}_{( 1 \; 00 ) , theo retical} / {I}_{( 002 ) , theoretical}} = \frac{{I}_{( 100 ) , sample} / {I}_{( 0 \; 02 ) , sample}}{0.147}$$

Examples 1 to 4 (EX1 to EX4)

Ultra-high molecular weight polyethylene (UHMWPE) powder (obtained under the trade designation “GUR-2126” from Celanese Corporation, Irvine, TX, US) was metered into the feed funnel of a twin-screw extruder (25 mm co-rotating twin screw extruder, Berstorff, Germany) at 200 rpm, 93° C., from a powder feeder (KT20, Coperion K-Tron, Stuttgart, Germany) at the rate shown in Table 1. Mineral oil (Kaydol White Mineral Oil from Brenntag Great Lakes, LLC) was pumped into the open barrel zone 2 of the extruder at 93° C. using a gear pump (Zenith Pumps, Monroe, NC, US) and Coriolis mass flow meter (Micromotion mass flow meter, Emerson Electric Co, St. Louis, MO, US) at the rate shown in Table 1, mixed and heated to 204° C. to melt the UHMWPE into the mineral oil. Finally, hexagonal boron nitride particles (BN; of the grade shown in Table 1, 3M Company, St. Paul, MN, US) was fed from a powder feeder into a side stuffer (Side Feeder, Century Extrusion, Travers City, MI, US) at 100 rpm connected to zone 4 of the twin screw extruder at 204° C. and was incorporated into the melt. The extruder mixed, dispersed, and increased the temperature of the melt making a stable mixture (i.e., a suspension). The mixture was then extruded through a drop die (6″ (15.24 cm), Wide Ultraflex U40, Nordson Extrusion Dies LLC, Chippewa Falls, WI, US) at 180° C. onto a smooth casting roll at 60° C. and the speed shown in Table 1 and quenched to form a film. Upon quenching, the ultra-high molecular weight polyethylene phase-separated from the suspension forming a phase separated porous polymeric network structure connecting the hexagonal boron nitride particles and mineral oil filling the voids. The mineral oil in the film was then extracted with 3M NOVEC 72DE (3M Company, St. Paul,

MN, US) by running the film through a counter current extraction bath at a rate of 10 fpm (feet per minute). The bath having a total of 300 gallon capacity divided into seven tanks. 3M NOVEC 72DE exchange rate to the bath was 52 gallons per hour. The film was then conveyed through a dryer at 83° C. to evaporate and recover the NOVEC 72DE, and a porous film was obtained. For each sample, 10 to 50 yards of the porous film were produced.

TABLE 1

| | EX1 | EX2 | EX3 | EX4 |
|---|---|---|---|---|
| UHMWPE feed rate [lb/hr] | 0.75 | 0.75 | 0.46 | 0.75 |
| Mineral oil feed rate [lb/hr] | 4.2 | 4.2 | 4.2 | 4.2 |
| Boron nitride grade | CFP | CFF | CFA | CFA |
| | 012P | 500-15 | 250S | 250S |
| Boron nitride feed rate [lb/hr] | 5.05 | 5.05 | 5.63 | 5.05 |
| Casting roll speed [fpm] | 2.1 | 2.1 | 4.2 | 2.1 |
| BN content [wt.-%] | 87.1 | 87.1 | 92.4 | 92.1 |

CFP 012P are boron nitride agglomerates having a mean agglomerate size (d₅₀) of 150 μm and are made from primary particles having a mean particle size (d₅₀) of 12 μm (available from 3M Company, St. Paul, MN, USA under the trade designation “3M™ Boron Nitride Powder Cooling Filler Platelets CFP 012P”).

CFF 500-15 are flake-shaped boron nitride agglomerates having a mean agglomerate size (d₅₀) of 310 μm and are made from primary particles having a mean particle size (d₅₀) of 15 μm (available from 3M Company, St. Paul, MN, USA under the trade designation “3M™ Boron Nitride Powder Cooling Filler Flakes CFF 500-15”).

CFA 250S are spherical boron nitride agglomerates (made from platelet-shaped boron nitride particles) having a mean agglomerate size (d₅₀) of 130 μm (available from 3M Company, St. Paul, MN, USA under the trade designation “3M™ Boron Nitride Powder Cooling Filler Agglomerates CFA 250S”).

The test results of the obtained porous film are shown in Table 2.

TABLE 2

| | EX1 | EX2 | EX3 | EX4 |
|---|---|---|---|---|
| Thickness of porous film [mil] | 24.5 | 20 | 11.84 | 24.5 |
| Thickness of porous film [mm] | 0.622 | 0.508 | 0.301 | 0.622 |
| Mass of disc (47 mm Ø) of porous film [g] | 0.9112 | 0.6954 | 0.4182 | 1.0837 |
| Density of porous film [g/cm³] | 0.85 | 0.77 | 0.80 | 1.01 |
| Porosity of porous film [%] | 55.5 | 58.7 | 60.5 | 50.2 |
| Air flow resistance (Gurley), 50 cm³, of porous film [sec] | 550.3 | 422.4 | 105.5 | 161.7 |
| Limiting pore diameter of porous film (bubble point | 0.27 | 0.29 | 0.51 | 0.64 |
| pressure test) [μm] | | | | |
| In-plane thermal conductivity of porous film [W/m*K] | 1.63 | 1.67 | n.m.*⁾ | 1.96 |

*⁾n.m. = not measured

The obtained porous film was subsequently calendered to reduce the porosity and improve the thermal conductivity. This was done by running 3 inches wide samples at 4 fpm through two smooth 10 inches diameter horizontal calender rolls set at a force of 4000 pli (pounds per linear inch).

The test results of the obtained densified film are shown in Table 3.

TABLE 3

| | EX1 | EX2 | EX3 | EX4 |
|---|---|---|---|---|
| Thickness of densified film [mil] | 9 | 6 | 5.5 | 9.5 |
| Thickness of densified film [mm] | 0.229 | 0.152 | 0.140 | 0.241 |
| Mass of disc (12.7 mm Ø) of | 0.054 | 0.042 | 0.037 | 0.065 |
| densified film [g] | | | | |
| Density of densified film [g/cm³] | 1.85 | 2.21 | 2.09 | 2.14 |
| Porosity of densified film [%] | 2.5 | 0 | 0 | 0 |
| In-plane thermal conductivity of | 22.2 | 25.7 | 38.0 | 27.1 |
| densified film [W/m*K] | | | | |
| Through-plane thermal | 1.60 | 1.61 | 2.79 | 2.55 |
| conductivity of densified film | | | | |
| [W/m*K] | | | | |

The obtained densified film was subsequently cut with scissors into 1″×2″ strips which were stacked between two release liner films and pressed in a heated hydraulic press at 149° C. (300° F.), gradually increasing pressing force to 5000 lbf over 5 minutes with 0.580″ shims on two opposing sides of the stack to keep the stack vertical. The number of strips which were stacked is shown in Table 4. The obtained pressed film stack was a bonded block (or bonded film stack) made from the stacked film strips and was removed from the hydraulic press and allowed to cool to room temperature (23° C.) before cutting off sheets using a razor blade to cut through all of the film layers. In the sheets obtained by cutting, the hexagonal boron nitride particles are oriented perpendicular to the plane of the sheet.

The test results of the obtained sheet are shown in Table 4.

TABLE 4

| | EX1 | EX2 | EX3 | EX4 |
|---|---|---|---|---|
| Number of layers of stack | 80 | 100 | 130 | 70 |
| Thickness of sheet [mil] | 42.1 | 80.7 | 36.2 | 74.8 |
| Thickness of sheet [mm] | 1.069 | 2.050 | 0.919 | 1.900 |
| Mass of disc (12.7 mm Ø) of | 0.223 | 0.406 | 0.193 | 0.407 |
| sheet [g] | | | | |
| Density of sheet [g/cm³] | 1.65 | 1.56 | 1.66 | 1.69 |
| Porosity of sheet [%] | 9.5 | 9.0 | 12.4 | 7.6 |
| Heat Capacity [J/g ° C.] | 1.02 | 1.01 | 0.93 | 0.96 |
| Through-plane thermal | 16.2 | 17.8 | 21.0 | 18.3 |
| conductivity of sheet [W/m*K] | | | | |
| Shore A hardness of sheet | 98 | 95 | 98 | 98 |
| Orientation Index | 14.4 | 7.7 | 9.9 | 9.7 |
| BN content of sheet [wt.-%] | 87.1 | 87.1 | 92.4 | 92.1 |
| UHMWPE of sheet [wt.-%] | 12.9 | 12.9 | 7.6 | 7.9 |

### Example 5 (EX5)

For Example 5, a densified film was prepared as described for Example 1, with the exceptions that extruding was performed at 193° C. (380° F.) instead of 180° C., a drop die of 8″ was used instead of 6″ for extruding, counter current extraction was performed at a rate of 2 fpm, and the formulation used was as shown in Table 5.

TABLE 5

| | EX5 |
|---|---|
| UHMWPE feed rate [lb/hr] | 0.46 |
| Mineral oil feed rate [lb/hr] | 4.2 |
| Boron nitride grade | CFA 50 |
| Boron nitride feed rate [lb/hr] | 5.63 |
| Casting roll speed [fpm] | 2.1 |
| BN content [wt.-%] | 92.5 |

CFA 50 is a mix of boron nitride agglomerates, platelets and clusters with 50 μm protective screening and a mean particle size (d₅₀) of 20 μm (available from 3M Company, St. Paul, MN, USA under the trade designation “3M™ Boron Nitride Powder Cooling Filler Agglomerates CFA 50”).

Test results of the densified film which was made following the procedure described for Example 1 are shown in Table 6.

TABLE 6

| | EX5 |
|---|---|
| Thickness of densified film [mil] | 6.3 |
| Thickness of densified film [mm] | 0.160 |
| Mass of disc (12.7 mm Ø) of densified film [g] | 0.040 |
| Density of densified film [g/cm³] | 1.92 |
| Porosity of densified film [%] | 5.3 |
| In-plane thermal conductivity of densified film [W/m*K] | 41.6 |
| Through-plane thermal conductivity of densified film [W/m*K] | 2.56 |

The obtained densified film was subsequently cut with scissors into 2″×2″ strips which were stacked between two release liner films and pressed in a heated hydraulic press at 149° C. (300° F.), gradually increasing pressing force to 2500 lbf over 2.5 minutes, with 1.375″ shims on two opposing sides of the stack to keep the stack vertical. The number of strips which were stacked is shown in Table 7. The obtained pressed film stack was a bonded block (or bonded film stack) made from the stacked film strips and was removed from the hydraulic press and allowed to cool to room temperature (23° C.). The bonded block was then placed in a lab oven at 149° C. for 10 min. The oven warmed bonded block was then quickly placed back in the heated hydraulic press at 176.6° C. (350° F.) and compressed by gradually increasing pressing force to 1700 lbf over 3 minutes. The bonded block was then removed from the hydraulic press and allowed to cool to room temperature (23° C.) before cutting off sheets using a skiving knife to cut through all of the film layers. In the sheets obtained by cutting, the hexagonal boron nitride particles are oriented in a direction perpendicular to the direction of the plane of the sheet.

The test results of the obtained sheet are shown in Table 7.

TABLE 7

| | EX5 |
|---|---|
| Archimedes Density of sheet [g/cm³] | 1.83 |
| Porosity of sheet [%] | 9.9 |
| Through-plane thermal conductivity of sheet [W/m*K] | 20.0 |
| BN content of sheet [wt.-%] | 92.5 |
| UHMWPE content of sheet [wt.-%] | 7.55 |

### Examples 6 to 8 (EX6 to EX8)

For Examples 6 to 8, porous films were prepared with the composition and the preparation method as described for Example 5, with the exception that the casting roll speed was 3 fpm. No calendering step was performed after obtaining the porous film. The porous film was then cut with scissors into 1″×1″ squares. For stacking and pressing the squares, i.e., for stacking multiple layers of the porous film and for pressing the film stack, a steel mold was used to constrain the stack in x- and y-direction. The steel mold had a cavity having a width of 1.0625″, a length of 1.0625″, a height 1.5″, and a top plunger, and was placed into an oven at 300° F. (149° C.) for 30 minutes to pre-heat the mold. The mold was removed from the oven and the 1″×1″ squares were stacked into the mold to a height of 1.4″. A release liner was placed on the top and bottom of the stack. The top plunger was inserted, and the mold and stacked film squares were placed in the oven at 300° F. (149° C.) for 15 minutes. The mold and film stack were then quickly removed from the oven and placed on a heated hydraulic press at 176.6° C. (350° F.) and pressed by gradually increasing force to the value shown in Table 8 over 3 minutes. The mold was then removed from the hydraulic press and opened; additional film squares were added. The heating, pressing, and addition of additional squares was then repeated three times until the stack was approximately 1″ heigh. The obtained pressed film stack was a bonded block (or bonded film stack) made from the stacked film squares and was removed from the hydraulic press and allowed to cool to room temperature (23° C.) before cutting off sheets using a bandsaw to cut through all of the film layers. In the sheets obtained by cutting, the hexagonal boron nitride particles are oriented in a direction perpendicular to the direction of the plane of the sheet.

The results are shown in Table 8.

TABLE 8

| | EX6 | EX7 | EX8 |
|---|---|---|---|
| Number of layers of stack | 188 | 184 | 181 |
| Pressing Force [lbf] | 10,000 | 5,000 | 2,500 |
| Pressing Pressure [psi] | 10,000 | 5,000 | 2,500 |
| Pressing Pressure [MPa] | 69 MPa | 34.5 MPa | 17.2 MPa |
| Thickness of sheet [mm] | 1.06 | 1.05 | 1.09 |
| Mass of disc (12.7 mm Ø) | 0.2425 | 0.2367 | 0.2372 |
| of sheet [g] | | | |
| Archimedes Density | 1.97 | 1.96 | 1.86 |
| of sheet [g/cm³] | | | |
| Porosity of sheet [%] | 2.86 | 3.36 | 8.62 |
| Heat Capacity [J/g ° C.] | 0.87 | 0.85 | 0.86 |
| Through-plane thermal | 64.0 | 64.5 | 49.2 |
| conductivity of | | | |
| sheet [W/m*K] | | | |
| Shore D hardness of sheet | 67.4 | 68.4 | 64.7 |
| BN content of sheet [wt.-%] | 92.4 | 92.4 | 92.4 |
| UHMWPE content | 7.6 | 7.6 | 7.6 |
| of sheet [wt.-%] | | | |
| Orientation Index | 19.7 | 18.8 | 20 |

As can be seen from Table 8, through-plane thermal conductivity of the sheet of Example 8 is significantly higher than of the sheet of Example 5, although porosity of the sheet of Example 8 is similar to porosity of the sheet of Example 5. This can be explained by the higher pressure used for pressing the film stack, which results in an increased particle-to-particle contact of the hexagonal boron nitride particles from layer to layer, i.e., between originally individual adjacent film layers in the bonded film stack formed upon pressing.

### Example 9 (EX9)

For Example 9, a porous film was prepared as described for Example 7. No calendering step was performed after obtaining the porous film. The porous film was then cut with scissors into 1.5×1.5″ squares. For stacking and pressing the squares, i.e., for stacking multiple layers of the porous film and for pressing the film stack, a steel mold was used to constrain the stack in x- and y-direction. The steel mold had a cavity having a width of 1.625″, a length of 1.625″, a height 2.625″, and a 1.25″ tall top plunger, and was placed into an oven at 300° F. (149° C.) for 60 minutes to pre-heat the mold. The mold was removed from the oven and the 1.5″×1.5″ squares were stacked into the mold to a height of 1.4″. A release liner was placed on the top and bottom of the stack. The top plunger was inserted into the mold. The mold and stacked film squares were placed in the oven at 300° F. (149° C.) for 15 minutes. The mold and stack were then quickly removed from the oven and placed on a heated hydraulic press at 176.6° C. (350° F.) and pressed by gradually increasing force to the value shown in Table 9 over 3 minutes. The mold was then removed from the hydraulic press and opened; additional film squares were added. The heating, pressing, and addition of additional squares was then repeated three times until the stack was approximately 1.5″ heigh. The obtained pressed film stack was a bonded block (or bonded film stack) made from the stacked film squares and was removed from the hydraulic press and allowed to cool to room temperature (23° C.) before cutting off sheets using a bandsaw to cut through all of the film layers. In the sheets obtained by cutting, the hexagonal boron nitride particles are oriented in a direction perpendicular to the direction of the plane of the sheet.

The results are shown in Table 9.

TABLE 9

| | EX9 |
|---|---|
| Number of layers of stack | 325 |
| Pressing Force [lbf] | 11,695 |
| Pressing Pressure [psi] | 5,198 |
| Pressing Pressure [MPa] | 35.8 MPa |
| Thickness of sheet [mm] | 1.91 |
| Mass of disc (33.0 mm Ø) of sheet [g] | 3.0747 |
| Archimedes Density of sheet [g/cm³] | 1.896 |
| Porosity of sheet [%] | 6.7 |
| Heat Capacity [J/g ° C.] | 0.85 |
| In-plane thermal conductivity of sheet [W/m*K] | 14.1 |
| Through-plane thermal conductivity of sheet [W/m*K] | 45.7 |
| Shore D hardness of sheet | 68.1 |
| BN content of sheet [wt.-%] | 92.4 |
| UHMWPE content of sheet [wt.-%] | 7.6 |
| Orientation Index | 8.5 |
| Dielectric constant (Dk) at 5.2 GHz | 3.9 |
| Dielectric dissipation factor (Df) at 5.2 GHz | 0.0002 |

### Examples 10 and 11 (EX10 and EX11)

A plastic mixing cup (obtained under the trade designation “MAX 100 CUP”) for a speed mixer (obtained under the trade designation “SPEEDMIXER DAC 150.1 FV”; both from FlackTek, Inc., Landrum, SC, US) was charged with ultra-high molecular weight polyethylene (UHMWPE) powder (obtained under the trade designation “GUR-2126” from Celanese Corporation, Irvine, TX, US), paraffin (obtained under the trade designation “ISOPAR G” from Brenntag Great Lakes, Inc., Wauwatosa, WI, US) and hexagonal boron nitride powder (of the grade shown in Table 10, 3M Company, St. Paul, MN, US) with the amounts shown in Table 10. The UHMWPE, the paraffin and the hexagonal boron nitride powder were mixed in the speed mixer at 1000 rpm for 1 minute and subsequently at 2500 rpm for 30 seconds. The obtained slurry was then stirred by hand with a wooden tongue depressor to remove materials from corners and side of the cup and mixed a second time at 1000 rpm for 1 minute and subsequently at 2500 rpm for 30 seconds.

TABLE 10

| | EX10 | EX11 |
|---|---|---|
| UHMWPE mass [g] | 3.033 | 12.185 |
| Isopar G mass [g] | 43.0 | 43.0 |
| Boron nitride grade | CFP 007HS | CFP 007HS |
| Boron nitride mass [g] | 38.63 | 29.48 |
| BN content [wt.-%] | 92.7 | 70.8 |

CPF 007HS are high surface area boron nitride platelets having a mean particle size (d₅₀) of 7 μm and a controlled top size of 50 μm (available from 3M Company, St. Paul, MN, USA under the trade designation “3M™ Boron Nitride Powder Cooling Filler Platelets CFP 007HS”).

After mixing, the slurry was applied with a tongue depressor at room temperature (23° C.) to a 3-mil (75-micrometer) polyester (PET) liner, then another 3-mil (75-micrometer) PET liner was applied on top of the slurry to sandwich the slurry. The slurry was then spread between the PET liners by using a notch bar set to a gap of 30 mils (762 micrometers) for the wet coating thickness (not including the liners).

The sandwiched, formed slurry was placed on an aluminum tray and placed in an oven at 150° C. (302° F.) for 5 minutes to activate (i.e., to allow the UHMWPE to dissolve into the solvent forming a single phase). The tray with the activated sandwiched formed slurry was removed from the oven, and the sandwich formed slurry and liners were placed on a granite block to air cool to ambient temperature (about 23° C.) forming a solvent filled (i.e., paraffin filled) porous film sandwiched between two liners. The top liner was removed exposing the porous film to air. The porous film on a PET liner on the tray was inserted into an oven at 100° C. (212° F.) for 45 minutes to evaporate the paraffin. After evaporation of the paraffin, the porous film on the PET liner was removed from the oven, allowed to cool to ambient temperature (23° C.), and then the liner was removed to obtain a porous film (i.e., a porous polymeric network comprising hexagonal boron nitride particles).

No calendering step was performed after obtaining the porous film. The obtained porous film was then cut into 1″×1″ squares. For stacking and pressing the squares, i.e., for stacking multiple layers of the porous film and for pressing the film stack, a steel mold was used to constrain the stack in x- and y-direction. The steel mold had a cavity having a width of 1.0625″, a length of 1.0625″, a height of 1.5″, and a top plunger, and was placed into an oven at 300° F. (149° C.) for 30 minutes to pre-heat the mold. The mold was removed from the oven and the 1″×1″ squares were stacked into the mold to a height of 1.4″. A release liner was placed on the top and bottom of the stack. The top plunger was inserted, and the mold and stacked film squares were placed in an oven at 300° F. (149° C.) for 15 minutes. The mold and film stack were then quickly removed from the oven and placed on a heated hydraulic press at 176.6° C. (350° F.) and pressed by gradually increasing force to 2000 lbf (corresponding to a pressing pressure of 2000 pounds per square inch (13.8 MPa)) over 3 minutes. The mold was then removed from the hydraulic press and opened, and additional film squares were added. The process was then repeated three times until the stack was approximately 1″ heigh. The obtained pressed film stack was a bonded block (or bonded film stack) made from the stacked film squares and was removed from the hydraulic press and allowed to cool to room temperature (23° C.) before cutting off sheets using a bandsaw to cut through all of the film layers. In the sheets obtained by cutting, the hexagonal boron nitride particles are oriented in a direction perpendicular to the direction of the plane of the sheet.

The test results of the obtained sheet are shown in Table 11.

TABLE 11

| | EX10 | EX11 |
|---|---|---|
| Number of layers of stack | 80 | 64 |
| Thickness of sheet [mil] | 40.5 | 41.3 |
| Thickness of sheet [mm] | 1.03 | 1.05 |
| Mass of disc (12.7 mm Ø) of sheet [g] | 0.2006 | 0.1889 |
| Density of sheet [g/cm³] | 1.54 | 1.42 |
| Porosity of sheet [%] | 21.8 | 0.5 |
| Through-plane thermal conductivity of sheet [W/m*K] | 22.0 | 17.2 |
| Shore D hardness of sheet | 52.7 | 70.0 |
| BN content of sheet [wt.-%] | 92.7 | 70.8 |
| UHMWPE content of sheet [wt.-%] | 7.3 | 29.2 |
| Orientation Index | 16.5 | 9.2 |

### Comparative Examples 1 to 3 (CEX1 to CEX3)

Comparative Examples 1 to 3 were made using silicone at the same volume percent loading of hexagonal boron nitride particles as for Examples 10 to 12. A plastic mixing cup (obtained under the trade designation “MAX 100 CUP”) for a speed mixer (obtained under the trade designation “SPEEDMIXER DAC 150.1 FV”; both from FlackTek, Inc., Landrum, SC, US) was charged with a two-part silicone (obtained under the trade designation “Sylgard 184” from Dow Chemical Co., Midland, MI, US) and hexagonal boron nitride particles (of the grade shown in Table 12, 3M Company, St. Paul, MN, US) with the amounts shown in Table 12. The two-part silicone and the hexagonal boron nitride particles were mixed in the speed mixer at 3500 rpm for 30 seconds.

TABLE 12

| | CEX1 | CEX2 | CEX3 |
|---|---|---|---|
| Sylgard 184 Part A mass [g] | 7.233 | 2.473 | 5.709 |
| Sylgard 184 Part B mass [g] | 0.723 | 0.247 | 0.571 |
| Boron nitride grade | CFP 007HS | CFP 007HS | CFP 007HS |
| Boron nitride mass [g] | 26.04 | 31.28 | 13.72 |
| BN content [wt.-%] | 76.6 | 92.0 | 68.6 |

The obtained slurry was then placed between two PET release liners and pressed on a heated hydraulic press at 130° C. with 0.576″ shims to attempt forming a film. The samples were removed from the hydraulic press, allowed to cool to room temperature (23° C.) and the release liners were removed to obtain the silicone/boron nitride samples.

The test results of the silicon/boron nitride samples are shown in Table 13.

TABLE 13

| | CEX1 | CEX2 | CEX3 |
|---|---|---|---|
| Film sample could be made [yes/no] | yes | No | yes |
| Film sample brittle [yes/no] | yes | — | no |

For Comparative Example 1, when attempting to form a film, the obtained sample was too brittle to be able to cut strips from it and it was not possible to form a film stack without the layers crumbling. The sample was dusty around the edges and easily broke when pressure was applied to it.

For Comparative Example 2, when attempting to form a film, the obtained sample looked like a pile of powder. It was not possible to form a stack of film layers.

For Comparative Example 3, the obtained film sample was subsequently cut with a razor into 2″×2″ squares. A thin layer of two-part silicone was applied to the top surface of the squares with a foam tipped applicator and 6 film layers were stacked to form a block with silicone between each layer. The block was then placed between 0.575″ shims in a heated hydraulic press at 130° C. and pressed for 30 minutes to cure the silicone. The bonded block was then removed from the hydraulic press and allowed to cool to room temperature (23° C.) before cutting off sheets using a bandsaw to cut through all of the layers.

The test results of the obtained sheet are shown in Table 14.

TABLE 14

| | CEX1 | CEX2 | CEX3 |
|---|---|---|---|
| Stack could be made [yes/no] | no | No | yes |
| Number of layers of sheet | — | — | 6 |
| Thickness of sheet [mil] | — | — | 36.22 |
| Thickness of sheet [mm] | — | — | 0.920 |
| Mass of disc (12.7 mm Ø) of sheet [g] | — | — | 0.1618 |
| Density of sheet [g/cm³] | — | — | 1.39 |
| Porosity of sheet [%] | — | — | 1.47 |
| Through-plane thermal conductivity of sheet | — | — | 5.9 |
| [W/m*K] | | | |
| Shore D hardness of sheet | — | — | 30 |
| BN content of sheet [wt.-%] | — | — | 68.6 |
| Sylgard content of sheet [wt.-%] | — | — | 31.4 |
| Orientation Index | | | 4.0 |

It can be seen from Table 14 that through-plane thermal conductivity for Comparative Example 3 is lower than for Example 11 although both samples had similar contents of hexagonal boron nitride particles (about 70 wt.-%). For Comparative Examples 1 and 2, a film stack could not be made and thus a sheet could not be sliced in a direction perpendicular to the planes of the stacked film layers.

### Examples 12 and 13 (EX12 and EX13)

For Examples 12 and 13, a porous film was prepared following the procedure described for Examples 10 and 11, with the exception that the formulations shown in Table 15 were used. Mineral was obtained under the trade designation “Kaydol White Mineral Oil” from Brenntag Great Lakes, LLC). Upon evaporation of the paraffin filled porous film (100° C., 45 min), a porous film was obtained which comprises the mineral oil in the porous polymeric network.

TABLE 15

| | EX12 | EX13 |
|---|---|---|
| UHMWPE mass [g] | 1.953 | 2.022 |
| Isopar G mass [g] | 30.14 | 45.0 |
| Mineral oil mass [g] | 1.256 | 1.230 |
| Boron nitride grade | CFA 150 | CFA 150 |
| Boron nitride mass [g] | 23.05 | 38.41 |
| BN content [wt.-%] | 87.8 | 92.2 |
| Mineral oil content [wt.-%] | 4.8 | 3.0 |
| UHMWPE content [wt.-%] | 7.4 | 4.8 |

CFA 150 are boron nitride agglomerates of crystalline boron nitride platelets having a mean agglomerate size (d₅₀) of 150 μm (available from 3M Company, St. Paul, MN, USA under the trade designation “3M™ Boron Nitride Powder Cooling Filler Agglomerates CFA 150”).

The obtained porous film was subsequently calendered to reduce the porosity and improve the thermal conductivity. This was done by running 3 inches wide samples at 4 fpm through two smooth 10 inches diameter horizontal calender rolls set at a force as shown in Table 16.

The test results of the obtained densified film are shown in Table 16.

TABLE 16

| | EX12 | EX13 |
|---|---|---|
| Calender force [pli] | 2000 | 6000 |
| Thickness of densified film [mil] | 8.6 | 5.8 |
| Thickness of densified film [mm] | 0.218 | 0.147 |
| Mass of disc (25.4 mm Ø) of densified film [g] | 0.1841 | 0.1312 |
| Density of densified film [g/cm³] | 1.66 | 1.76 |
| Porosity of densified film [%] | 12.5 | 12.7 |
| In-plane thermal conductivity | 20.1 | 32.4 |
| of densified film [W/m*K] | | |

The obtained densified film was subsequently cut with scissors into 1.5″×1.5″ strips which were stacked between two release liner films and pressed in a heated hydraulic press at 149° C. (300° F.) gradually increasing pressing force to 2500 lbf over 2.5 minutes with 1.375″ shims on two opposing sides of the stack to limit compression and keep the stack vertical. The number of strips which were stacked is shown in Table 17. The obtained pressed film stack was a bonded block (or bonded film stack) made from the stacked film strips and was removed from the hydraulic press and allowed to cool to room temperature (23° C.). The bonded block was then placed in a lab oven at 149° C. for 10 min. The oven warmed bonded block was then quickly placed back in the heated hydraulic press at 176.6° C. (350° F.) and compressed by gradually increasing pressing force to 1700 lbs over 3 minutes. The bonded block was then removed from the hydraulic press and allowed to cool to room temperature (23° C.) before cutting off sheets using a bandsaw to cut through all of the film layers. In the sheets obtained by cutting, the hexagonal boron nitride particles are oriented in a direction perpendicular to the direction of the plane of the sheet.

The test results of the obtained sheet are shown in Table 17.

TABLE 17

| | EX12 | EX13 |
|---|---|---|
| Number of layers of stack | 196 | 110 |
| Thickness of sheet [mil] | 40.16 | 32.77 |
| Thickness of sheet [mm] | 1.020 | 0.832 |
| Mass of disc (12.7 mm Ø) of sheet [g] | 0.1801 | 0.1495 |
| Density of sheet [g/cm³] | 1.39 | 1.42 |
| Porosity of sheet [%] | 16.7 | 17.5 |
| In-plane thermal conductivity of sheet [W/m*K] | 3.0 | n.m.*⁾ |
| Through-plane thermal | 12.1 | 21.3 |
| conductivity of sheet [W/m*K] | | |
| Shore D hardness of sheet | n.m.*⁾ | 38.2 |
| BN content of sheet [wt.-%] | 87.8 | 92.2 |
| Mineral oil content of sheet [wt.-%] | 4.8 | 3.0 |
| UHMWPE content of sheet [wt.-%] | 7.4 | 4.8 |
| Orientation Index | 7.1 | 11.6 |
| Dielectric constant (Dk) at 5.2 GHz | 3.2 | n.m.*⁾ |
| Dielectric dissipation factor (Df) at 5.2 GHz | 0.0003 | n.m.*⁾ |

*⁾n.m. = not measured

The hardness of the samples including mineral oil in the final sheet is lower than the hardness of the samples which do not include mineral oil in the final sheet.

### Example 14 (EX14)

For Example 14, a porous film was prepared with the composition and the preparation method as described for Example 13. No calendering step was performed after obtaining the porous film. The obtained porous film was then cut into 1″×1″ squares. For stacking the squares, i.e., for stacking multiple layers of the porous film, a steel mold was used to constrain the stack in x- and y-direction. The steel mold had a cavity having a width of 1.0625″, a length of 1.0625″, a height 1.5″, and a top plunger, and was placed into an oven at 300° F. (149° C.) for 30 minutes to pre-heat the mold. The mold was removed from the oven and the 1″×1″ squares were stacked into the mold to a height of 1.4″. A release liner was placed on the top and bottom of the stack. The top plunger was inserted and the mold and stacked film squares were placed in the oven at 300° F. (149° C.) for 15 minutes. The mold and stack were then quickly removed from the oven and placed on a heated hydraulic press at 176.6° C. (350° F.) and pressed by gradually increasing force to 2000 lbf (corresponding to a pressing pressure of 2000 pounds per square inch (13.8 MPa)) over 3 minutes. The mold was then removed from the hydraulic press and opened, and additional film squares were added. The process was then repeated three times until the stack was approximately 1″ heigh. The obtained pressed film stack was a bonded block (or bonded film stack) made from the stacked film squares and was removed from the hydraulic press and allowed to cool to room temperature (23° C.) before cutting off sheets using a bandsaw to cut through all of the film layers. In the sheets obtained by cutting, the hexagonal boron nitride particles are oriented in a direction perpendicular to the direction of the plane of the sheet.

The test results of the obtained sheet are shown in Table 18.

TABLE 18

| | EX14 |
|---|---|
| Number of layers of stack | 82 |
| Thickness of sheet [mil] | 40.5 |
| Thickness of sheet [mm] | 1.03 |
| Mass of disc (12.7 mm Ø) of sheet [g] | 0.2122 |
| Density of sheet [g/cm³] | 1.68 |
| Porosity of sheet [%] | 16.8 |
| Through-plane thermal conductivity of sheet [W/m*K] | 31.7 |
| Shore D hardness of sheet | 50.3 |
| Orientation Index | 4.5 |
| BN content of sheet [wt.-%] | 92.2 |
| Mineral oil content of sheet [wt.-%] | 3.0 |
| UHMWPE content of sheet [wt.-%] | 4.8 |

### Example 15 (EX15)

Example 15 was prepared by charging the 176.6° C. (350° F.) bowl of a mixer (Brabender CW DR-2051, Brabender GmbH & Co. KG, Duisburg, Germany) with 0.4561g of ultra-high molecular weight polyethylene (UHMWPE) powder, 12.6135 g of mineral oil (obtained under the trade designation “Kaydol White Mineral Oil” from Brenntag Great Lakes, LLC), 16.7774 g of hexagonal boron nitride particles (obtained under the trade designation “3M™ Boron Nitride Powder Cooling Filler Agglomerates CFA 50”, 3M Company, St. Paul, MN, USA), and 1.1309 g of elastomer (obtained under the trade designation Krayton 1645, Krayton Corporation, Houston, TX). The bowl was mixed at 50 rpm for 5 minutes to melt the UHMWPE and mix the components.

The melted suspension was removed from the bowl with a tongue depressor and placed between two heat stable release liners. It was then placed on a heated hydraulic press at 176.6° C. (350° F.) with a 61.5 mil shim on two opposite sides of the stack between the release liners to limit the compression and pressed by gradually increasing force to 3000 lbf over 5 minutes to form a film. The film was then removed from the hydraulic press and placed between cooling plates for 5 minutes to rapidly cool to room temperature (23° C.).

The liners were removed, and the film sample was washed three times in a pan of excess Novec 72DE with 10 minutes soaking time followed by draining and replacing the solvent each time. Following the last wash, the sample was allowed to dry at room temperature (23° C.) in a fume hood for at least 1 hour. The test results of the obtained porous film are shown in Table 19.

TABLE 19

| | EX15 |
|---|---|
| Thickness of porous film [mil] | 55.5 |
| Thickness of porous film [mm] | 1.41 |
| Mass of disc (25.4 mm Ø) of porous film [g] | 0.5993 |
| Density of porous film [g/cm³] | 0.84 |
| Limiting pore diameter of porous film (bubble | 2.72 |
| point pressure test) [μm] | |

The obtained porous film was cut into 3″ wide film strips, placed between two release liners and then calendered at 1000 pli and 5 fpm to densify the sample.

The test results of the obtained densified film are shown in Table 20.

TABLE 20

| | EX15 |
|---|---|
| Thickness of densified film [mil] | 8.6 |
| Thickness of densified film [mm] | 0.218 |
| Mass of disc (25.4 mm Ø) of densified film [g] | 0.1779 |
| Density of densified film [g/cm³] | 1.61 |
| Porosity of densified film [%] | 19.8 |
| In-plane thermal conductivity of densified film [W/m*K] | 15.2 |
| Through-plane thermal conductivity of densified film [W/m*K] | 1.37 |

The obtained densified film was then cut into 1″×1″ squares. For stacking the squares, i.e., for stacking multiple layers of the densified film, a steel mold was used to constrain the stack in x- and y-direction. The steel mold had a cavity having a width of 1.0625″, a length of 1.0625″, a height of 1.5″,and a top plunger, and was placed into an oven at 300° F. (149° C.) for 30 minutes to pre-heat the mold. The mold was removed from the oven and the 1″×1″ squares were stacked into the mold to a height of 1.4″. A release liner was placed on the top and bottom of the stack. The top plunger was inserted, and the mold and stacked film squares was placed in a lab oven at 300° F. (149° C.) for 15 minutes. The mold and stack were then quickly removed and placed on a heated hydraulic press at 176.6° C. (350° F.) and pressed by gradually increasing force to 2000 lbf (corresponding to a pressing pressure of 2000 pounds per square inch (13.8 MPa)) over 3 minutes. The mold was then removed from the hydraulic press and opened, and additional film squares were added. The process was then repeated three times until the stack was approximately 1″ heigh. The obtained pressed film stack was a bonded block (or bonded film stack) made from the stacked film squares and was removed from the hydraulic press and allowed to cool to room temperature (23° C.) before cutting off sheets using a bandsaw to cut through all of the film layers. In the sheets obtained by cutting, the hexagonal boron nitride particles are oriented in a direction perpendicular to the direction of the plane of the sheet.

The test results of the obtained sheets are shown in Table 21.

TABLE 21

| | EX15 |
|---|---|
| Thickness of sheet [mil] | 34.25 |
| Thickness of sheet [mm] | 0.87 |
| Mass of disc (12.7 mm Ø) of sheet [g] | 0.1749 |
| Density of sheet [g/cm³] | 1.59 |
| Porosity of sheet [%] | 9.16 |
| Through-plane thermal conductivity of sheet [W/m*K] | 24.7 |
| Shore D hardness of sheet | 39.6 |
| BN content of sheet [wt.-%] | 91.4 |
| Elastomer content of sheet [wt.-%] | 6.2 |
| UHMWPE content of sheet [wt.-%] | 2.4 |

The hardness of the samples including an elastomer in the final sheet is lower than the hardness of the samples which do not include an elastomer in the final sheet.

1. A sheet comprising a composite material comprising a polymer and hexagonal boron nitride particles, wherein the hexagonal boron nitride particles comprise platelet-shaped hexagonal boron nitride particles, and wherein the platelet-shaped hexagonal boron nitride particles are oriented in a direction perpendicular to the direction of the plane of the sheet, and wherein the composite material comprises at least 70 percent by weight of the hexagonal boron nitride particles, based on the total weight of the composite material, and wherein the sheet has a through-plane thermal conductivity of more than 12 W/m*K.

2. The sheet of claim 1, wherein the composite material is obtained by densifying a material comprising a porous network of the polymer.

3. The sheet of claim 1, wherein the composite material comprises at least 80 percent by weight, preferably at least 85 percent by weight, more preferably at least 90 percent by weight, more preferably more than 90 percent by weight of the hexagonal boron nitride particles, based on the total weight of the composite material.

4. The sheet of claim 1, wherein the sheet has a through-plane thermal conductivity of at least 15 W/m*K.

5. The sheet of claim 1, wherein the orientation index of the sheet is greater than 4.0.

6. The sheet of claim 1, wherein the composite material further comprises 0.1 to 10 percent by weight of mineral oil, based on the total weight of the composite material.

7. The sheet of claim 1, wherein the polymer is selected from the group consisting of polyurethane, polyester, polyamide, polyether, polycarbonate, polyimide, polysulfone, polyethersulfone, polyphenylene oxide, polyacrylate, polymethacrylate, polyacrylonitrile, polyolefin, styrene, styrene-based copolymer, styrene-base copolymer, chlorinated polymer, fluorinated polymer, copolymers of ethylene and chlorotrifluoroethylene, and combinations thereof.

8. The sheet of claim 17, wherein the polymer is an ultra-high molecular weight polyethylene having a number average molecular weight in a range from 5×10⁴ to 1×10⁷ g/mol.

9. The sheet of claim 1, wherein the composite material has a porosity of up to 40%.

10. The sheet of claim 1, wherein the sheet has a Shore D hardness of 30 to 150.

11. A process for producing a sheet according to claim 1, the process comprising
providing a polymer, a solvent, and hexagonal boron nitride particles comprising platelet-shaped hexagonal boron nitride particles,
combining the polymer, the solvent, and the hexagonal boron nitride particles to form a suspension of hexagonal boron nitride particles in a polymer-solvent solution, wherein the polymer in the polymer-solvent solution has a melting point, and wherein the solvent has a boiling point, and wherein combining the polymer, the solvent, and the hexagonal boron nitride particles is conducted at a temperature above the melting point of the polymer in the polymer-solvent solution, and below the boiling point of the solvent,
forming the suspension into a film, wherein the platelet-shaped hexagonal boron nitride particles are oriented in a direction parallel to the direction of the plane of the film,
inducing phase separation of the polymer from the solvent,
removing at least a portion of the solvent from the film to obtain a porous film,
optionally compressing the porous film to obtain a densified film,
stacking multiple layers either of the porous film or of the densified film one upon another to obtain a film stack,
pressing the film stack to obtain a bonded film stack, and
slicing a sheet from the bonded film stack in a direction perpendicular to the planes of the stacked film layers.

12. A process for producing a sheet according to claim 1, the process comprising
providing a polymer, a solvent, and hexagonal boron nitride particles comprising platelet-shaped hexagonal boron nitride particles,
combining the polymer, the solvent, and the hexagonal boron nitride particles to form a slurry, wherein the slurry is a suspension of the polymer and the hexagonal boron nitride particles in the solvent, and wherein the polymer has a melting point, and wherein the solvent has a boiling point, and wherein combining the polymer, the solvent, and the hexagonal boron nitride particles is conducted below the melting point of the polymer, and below the boiling point of the solvent,
forming the slurry into a film, wherein the platelet-shaped hexagonal boron nitride particles are oriented in a direction parallel to the direction of the plane of the film,
heating the film in an environment to retain at least 90 percent by weight of the solvent in the film, based on the weight of the solvent in the film, and solubilizing at least 50 percent by weight of the polymer in the solvent, based on the total weight of the polymer,
inducing phase separation of the polymer from the solvent,
removing at least a portion of the solvent from the film to obtain a porous film,
optionally compressing the porous film to obtain a densified film,
stacking multiple layers either of the porous film or of the densified film one upon another to obtain a film stack,
pressing the film stack to obtain a bonded film stack, and
slicing a sheet from the bonded film stack in a direction perpendicular to the planes of the stacked film layers.

13. The process of claim 11, further comprising heating the film stack prior to pressing the film stack.

14. The process of claim 11, wherein pressing the film stack is performed at a temperature of at least 110° F.

15. The process of claim 11, further comprising heating of the bonded film stack prior to slicing a sheet from the bonded film stack.

16. The process of claim 11, wherein pressing the film stack is performed under a pressing pressure of at least 2.0 MPa.

17. The process of claim 11, wherein pressing the film stack is performed in a pressing direction while constraining the film stack in a first direction perpendicular to the pressing direction.

18. The process of claim 11, wherein pressing the film stack is performed in a pressing direction while constraining the film stack in a first direction perpendicular to the pressing direction and in a second direction perpendicular to the pressing direction, and wherein the first direction is perpendicular to the second direction.
